(19) United States
(12) Patent Application Publication
(10) Pub. No.: US 2026/0150316 A1
(43) Pub. Date: May 28, 2026

(54) METHODS FOR FORMING SEMICONDUCTOR DEVICE HAVING NANOSHEET TRANSISTOR

(71) Applicant: TAIWAN SEMICONDUCTOR MANUFACTURING COMPANY, LTD., Hsinchu (TW)

(72) Inventors: Kuei-Yu KAO, Hsinchu (TW); Guan Kai HUANG, Changhua (TW); Chun-Yu LIN, Yilan (TW); Min-Chiao LIN, Hsinchu (TW); Yung-Chi CHANG, Hsinchu (TW)

(21) Appl. No.: 18/956,158

(22) Filed: Nov. 22, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018

(57) ABSTRACT

Various embodiments provide a method for forming a semiconductor device structure. The method includes forming a fin structure from a substrate, the fin structure comprises a plurality of nanostructured layers and a plurality of sacrificial nanostructured layers alternatingly stacked, forming a shallow trench isolation (STI) region on the substrate, forming a sacrificial gate structure with a first gate portion suspended over the STI region and a second gate portion on the fin structure, removing the sacrificial nanostructured layers in the fin structure to form first cavities, filling the first cavities with a sacrificial dielectric layer, removing edge portions of each sacrificial dielectric layer to form second cavities, filling the second cavities with a dielectric spacer, forming a source/drain (S/D) feature, the S/D feature being in contact with the nanostructured layers and the dielectric spacers, and replacing the sacrificial gate structure and the sacrificial dielectric layer with a gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, as dimensions of integrated circuits continue to scale to smaller sub-micron sizes in advanced node applications, it becomes an increasing challenge to reduce channel resistance while maintaining desired electric current for the device. Therefore, improved structures and methods for manufacturing the same are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device structure at an intermediate stage, in accordance with some embodiments.

FIGS. 2, 2A, 2B, 2C, 3, 3A, 3B, 3C, 4, 4A, 4B, 4C, 5, 5A, 5B, 5C, 6, 6A, 6B, and 6C illustrate different cross-sectional views of the semiconductor device structure of FIG. 1 at various stages of its fabrication process, in accordance with some embodiments.

FIGS. 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, and 15C are cross-sectional side views of various stages of manufacturing the semiconductor device structure taken along cross-section A-A, cross-section B-B, cross-section C-C of FIG. 6, in accordance with some embodiments.

FIG. 16 illustrates a cross-section view of the semiconductor device structure taken along cross-section B-B of FIG. 2, in accordance with some alternative embodiments.

FIGS. 17, 17A, 17B, 17C, 18, 18A, 18B, 18C, 19, 19A, 19B, 19C, 20A, 20B, 20C, 21A, 21B, 21C, 22A, 22B, and 22C are perspective view and/or cross-sectional side views of various stages of manufacturing the semiconductor device structure taken along cross-section A-A, cross-section B-B, cross-section C-C of FIG. 2, in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20 % of the value (e.g., ±1 %, ±2 %, ±3 %, ±4 %, ±5 %, ±10 %, ±10-15 %, ±15˜20 % of the value). These values are merely examples and are not intended to be limiting. The terms “about” and “substantially” can refer to a percentage of the values as interpreted by those skilled in relevant art(s) in light of the teachings herein.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

A GAA FET can include a base structure (also referred to as “a sheet base” and “a fin base”) disposed on a substrate, a shallow trench isolation (STI) region disposed adjacent to the base structure and on the substrate, source/drain (S/D) regions disposed on the substrate, nanostructured channel regions disposed on the base structure and between the S/D regions, and a gate structure (also referred to as a “GAA structure”) surrounding each of the nanostructured channel regions. The GAA structure includes an outer gate portion disposed on the STI region and an inner gate portion disposed on the nanostructured channel regions. The inner gate portion includes a top gate portion disposed on the topmost nanostructured channel region and a bottom gate portion disposed between the base structure and the bottommost nanostructured channel region.

One of the challenges of forming the GAA structure is preventing the bottom gate portion from extending into the base structure during the formation of the GAA structure, which places the bottom gate portion close to the S/D regions and increases the parasitic capacitance in the GAA FET. The bottom gate portion may extend into the base structure due to a trench formed in the base structure during the formation of the GAA structure in a gate replacement process. The gate replacement process includes forming a sacrificial gate structure (also referred to as a “dummy gate structure”) with a portion on the STI region, etching the sacrificial gate structure to form a gate opening, and forming the GAA structure in the gate opening. During the etching of the sacrificial gate structure, the STI region below the sacrificial gate structure may be over-etched, which leads to the base structure, adjacent to the STI region, being etched and an extended trench formed in the base structure.

To overcome the abovementioned challenges, the present disclosure provides exemplary structures and methods for improving the bottom surface profiles of the bottom gate portion of the GAA structure, which increases the spacing between the bottom gate portion and the S/D regions. Increasing the spacing between the bottom gate portion and the S/D regions can reduce or minimize the parasitic capacitance in the GAA FET, which can improve the reliability and performance of the GAA FET. In some embodiments, the portion of the sacrificial gate structure on the STI region can be separated by a spacer to prevent the etching of the STI region during the removal of the sacrificial gate structure. Preventing the etching of the STI region can prevent the etching of the base structure and the formation of the trench in the base structure. As a result, the bottom gate portion can be formed with a substantially planar bottom surface profile. In some embodiments, the portion of the sacrificial gate structure directly on the STI region can be formed with a tapered cross-sectional profile to prevent or minimize the etching of the STI region during the removal of the sacrificial gate structure. As a result, the formation of the trench in the base structure can be prevented or a narrow trench can be formed in the base structure. In some embodiments, the trench can be narrower than that formed with sacrificial gate structures having non-tapered (e.g., rectangular) cross-sectional profiles on the STI regions. Thus, by modifying the profiles of the sacrificial gate structure portions on the STI regions, the bottom surface profiles of the bottom gate portion can be improved to reduce or minimize the parasitic capacitance in the GAA FET.

In addition, prior to forming S/D regions, nanostructured sacrificial layers between nanostructured channel layers may be replaced with sacrificial dielectric layers. The sacrificial dielectric layers have minimum reaction with the nanostructured channel layers during subsequent high temperature process, such as forming S/D regions, and can be easily removed during the gate replacement process. Since the integrity and surface profile of the nanostructured channel layers are preserved during the gate replacement process, a channel resistance between a source feature and a drain feature can be reduced. As a result, the device performance is improved.

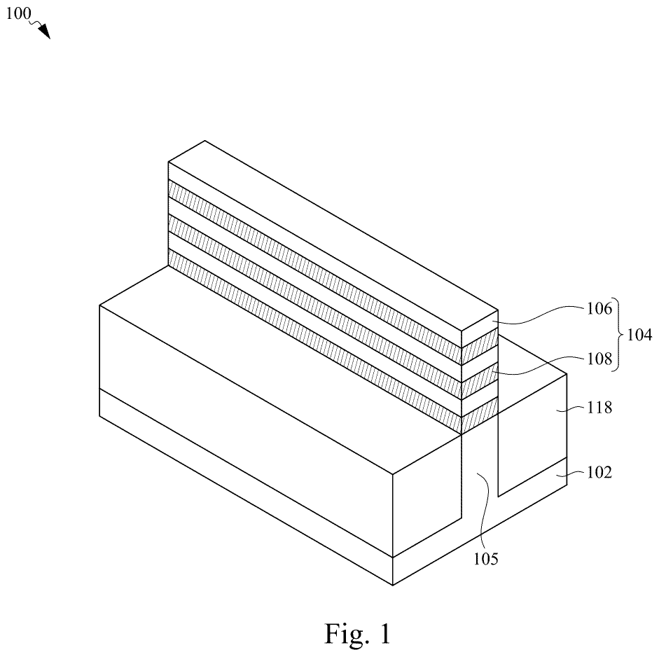

FIG. 1 is a perspective view of a semiconductor device structure 100 in accordance with some embodiments. The semiconductor device structure 100 includes a superlattice structure with a nanostructured layer and a nanostructured sacrificial layer formed on a base structure on a substrate. For example, a superlattice structure 104 (also referred to as “a nanosheet stack 104”) is formed on fin-shaped base structure 105, which may be a well portion formed on or extended from a substrate 102. Superlattice structure 104 can include nanostructured layers 106 and nanostructured sacrificial layers 108 arranged in an alternating configuration. Either of the nanostructured layers 106 and nanostructured sacrificial layers 108 may be or include a suitable semiconductor materials such as Si, Ge, SiGe, SiC, GeAs, GaP, InP, InAs, InSb, GaAsP, AlInAs, AlGaAs, InGaAs, GaInP, GaInAsP, or any combinations thereof. In some embodiments, nanostructured layers 106 can include a first semiconductor material, such as Si, and nanostructured sacrificial layers 108 can include a second semiconductor material, such as SiGe. The first semiconductor material and the second semiconductor material may be selected to have different etch selectivity and/or oxidation rates.

The substrate 102 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 102 is made of silicon. The substrate 102 may be doped or un-doped. The substrate 102 may be a bulk semiconductor substrate, such as a bulk silicon substrate that is a wafer, a silicon-on-insulator (SOI) substrate, a multi-layered or gradient substrate, or the like. The substrate 102 may include various regions that have been doped with impurities (e.g., dopants having p-type or n-type conductivity). Depending on circuit design, the dopants may be, for example phosphorus for n-well and/or an n-type field effect transistors (NFET) and boron for p-well and/or a p-type field effect transistors (PFET).

The superlattice structure 104 and the fin-shaped base structure 105 may be formed by patterning a hard mask layer (not shown) formed on the superlattice structure 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches in unprotected regions through the hard mask layer, through the superlattice structure 104 and the fin-shaped base structure 105, and into the substrate 102, thereby leaving the plurality of extending fin-like structures.

An STI region is formed on the substrate and adjacent to the base structure 105. For example, STI region 118 is formed on substrate 102 and adjacent to base structure 105. In some embodiments, the formation of STI regions 118 can include sequential operations of: (i) depositing a dielectric layer (not shown) having the material of STI region 118 on substrate 102 and superlattice structure 104, the dielectric layer fills the trenches between neighboring fin-like structures until the superlattice structure 104 is embedded in the dielectric layer; (ii) performing a chemical mechanical polishing (CMP) process so that top surfaces of the dielectric layer and superlattice structure 104 are substantially co-planar, and (iii) performing an etch-back recess process on the dielectric layer to form the semiconductor device structure 100 shown in FIG. 1. In some embodiments, a top surface of the STI region 118 may be level with or below a top surface of the base structure 105.

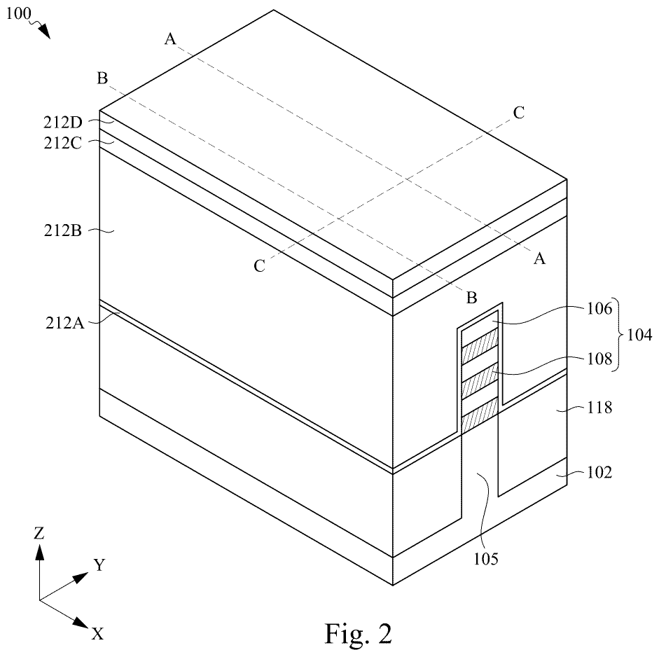

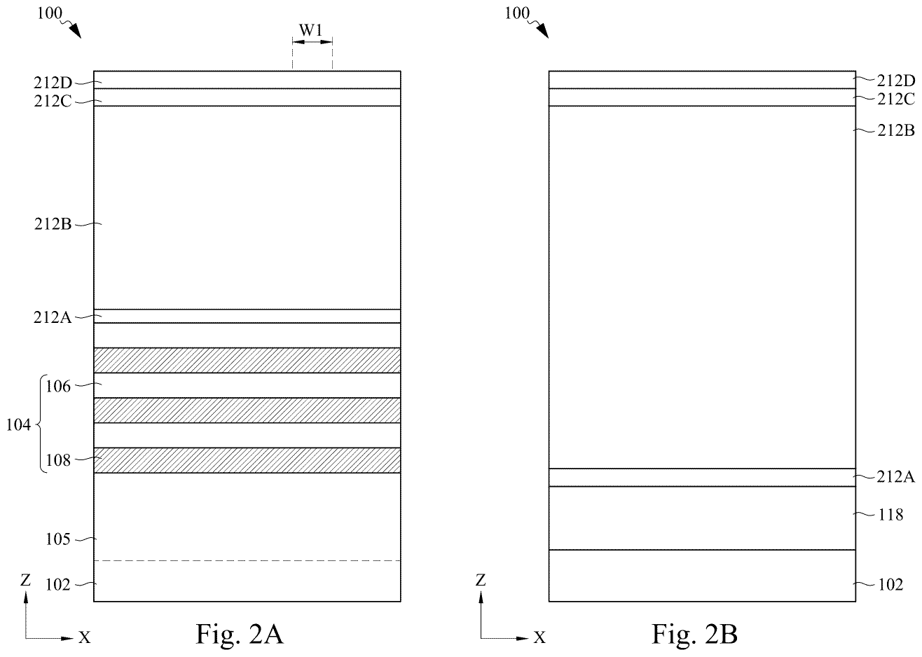

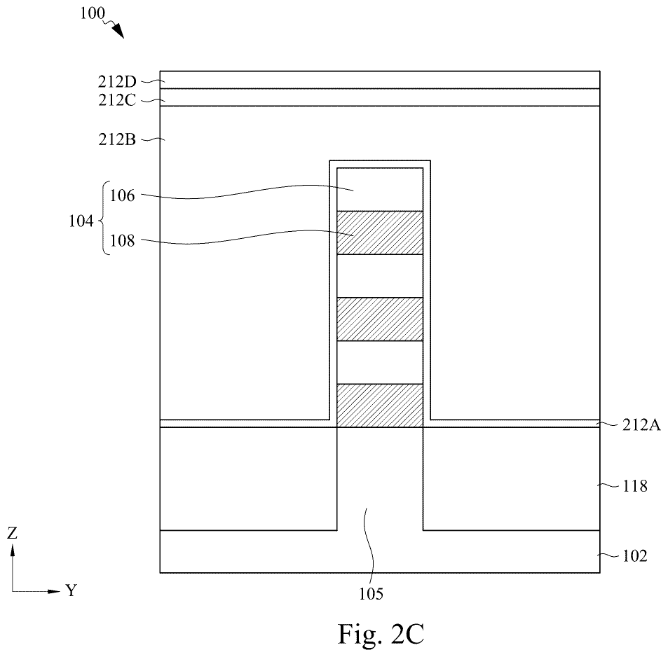

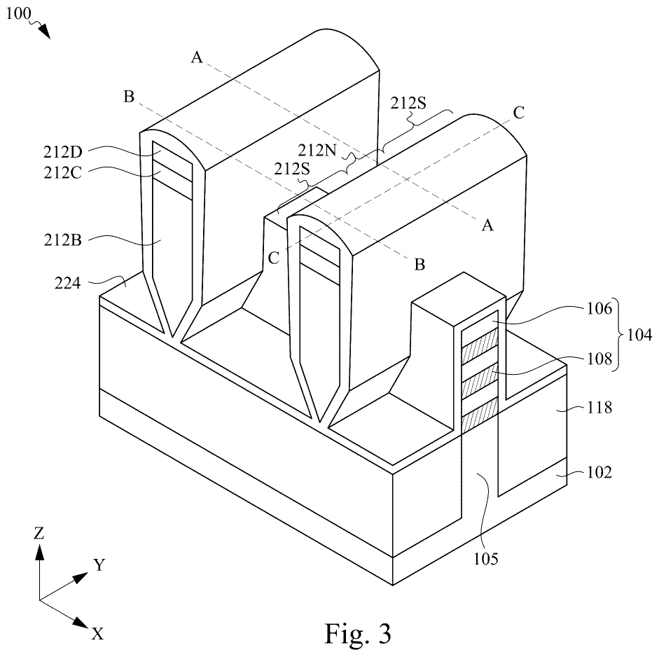

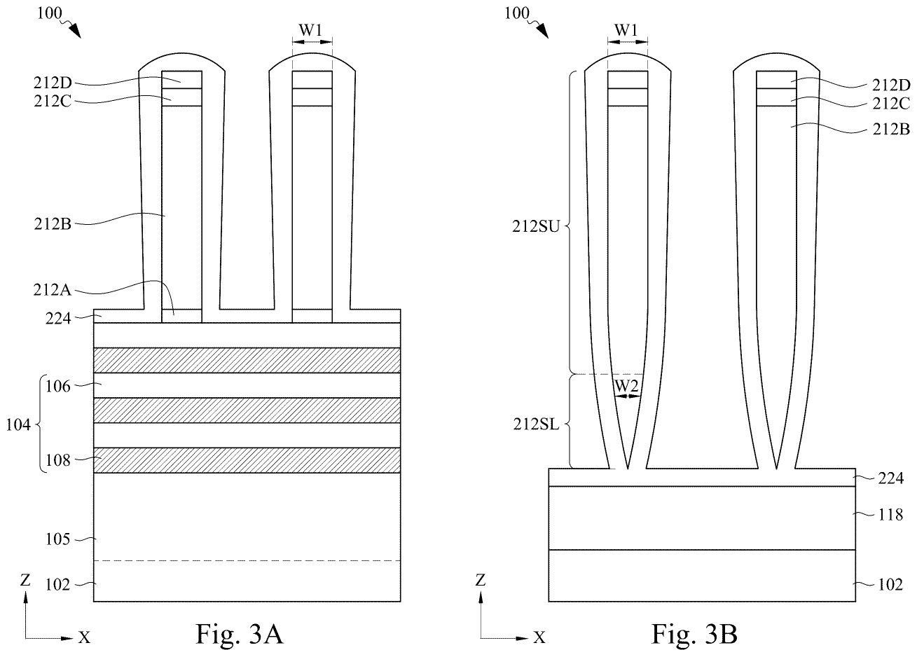

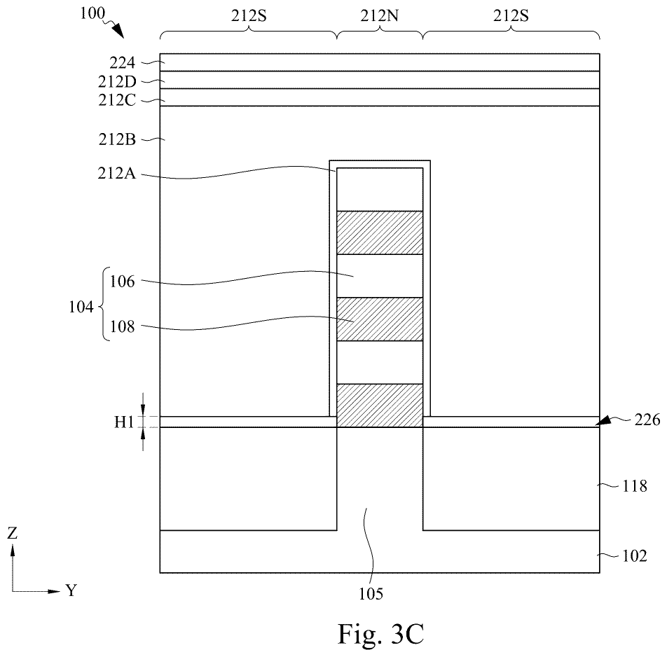

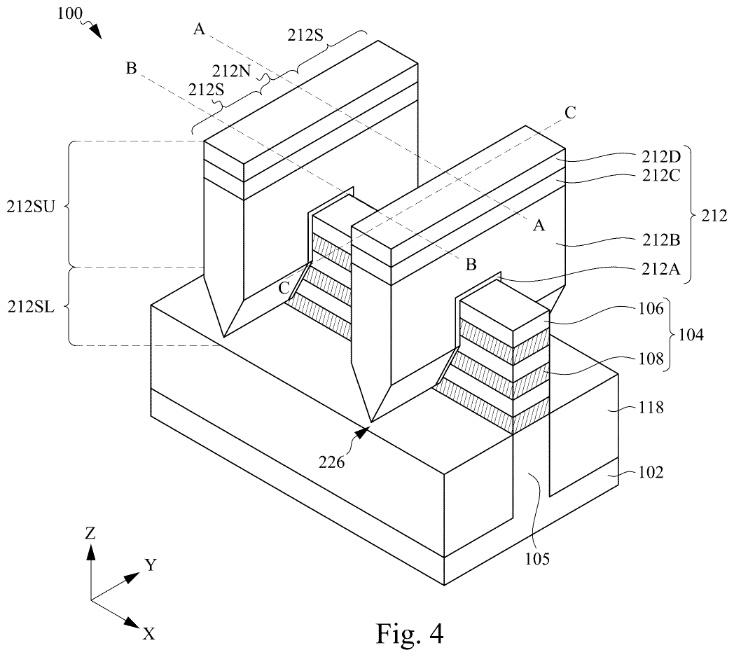

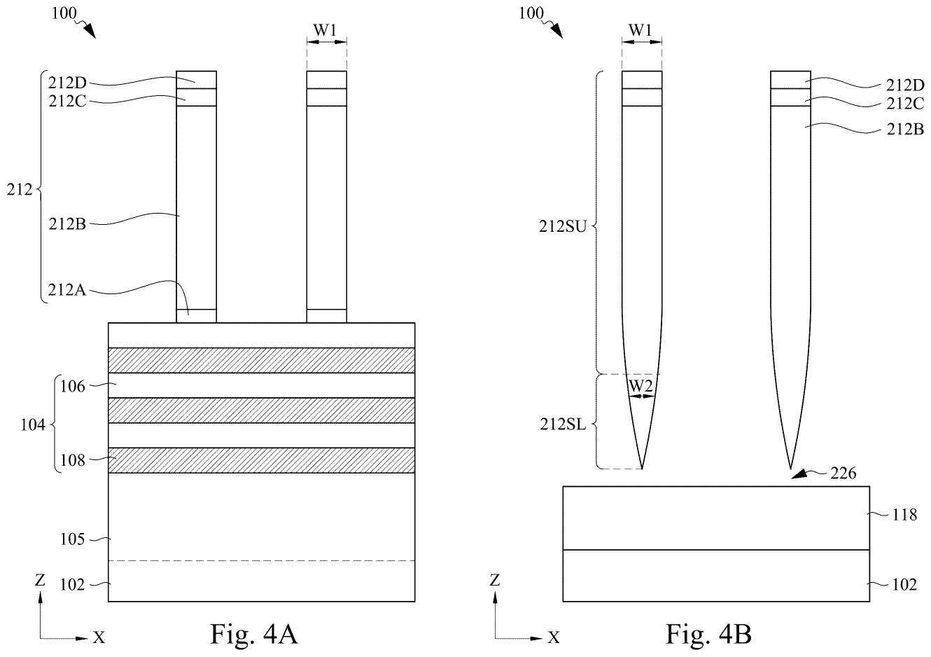

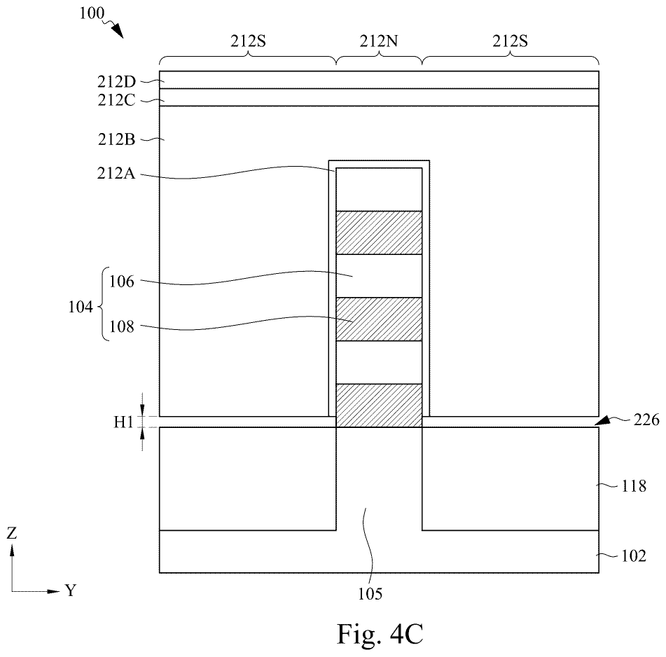

In FIG. 2, a sacrificial gate structure with a first portion on the superlattice structure 104 and a second portion suspended on the STI region 118 is formed. For example, as will be described with reference to FIG. 3, sacrificial gate structures 212 are formed with outer gate portions 212S suspended over the STI region 118 and inner gate portion 212N on the superlattice structure 104. In some embodiments, the formation of the sacrificial gate structure 212 can include sequential operations of: (i) depositing an oxide layer 212A substantially conformally on the STI regions 118 and the superlattice structure 104 of FIG. 1, as shown in FIGS. 2 and 2A-2C, (ii) depositing an amorphous, polycrystalline, or monocrystalline polysilicon layer 212B on the oxide layer 212A, as shown in FIGS. 2 and 2A-2C, (iii) depositing a nitride mask layer 212C (e.g., SiN layer) on polysilicon layer 212B, as shown in FIGS. 2 and 2A-2C, (iv) depositing an oxide mask layer 212D (e.g., SiO₂ layer) on the nitride mask layer 212C, as shown in FIGS. 2 and 2A-2C, (v) performing a lithographic patterning process (not shown) on the structures of FIGS. 2 and 2A-2C, (vi) performing a first etch process on the structures of FIGS. 2 and 2A-2C to form sacrificial gate structures 212 having the oxide layers (now IL layers) 212A, polysilicon structures 212B, nitride mask layers 212C, and oxide mask layers 212D, and a byproduct layer 224, as shown in FIGS. 3 and 3A-3C, and (vii) performing a second etch process (also referred to as a “purging process”) using hydrofluoric (HF) acid gas or solution on the structures of FIGS. 3 and 3A-3C to remove byproduct layer 224 and form sacrificial gate structures 212 with outer gate portions 212S suspended over the STI regions 118 and inner gate portion 212N directly on the superlattice structure 104, as shown in FIGS. 4 and 4A-4C.

In FIGS. 2, 2A-2C, 3, and 3A-3C, each of the outer gate portions 212S can have (i) an upper gate portion 212SU (FIG. 3B) having a first portion of polysilicon structure 212B, the nitride mask layer 212C, and the oxide mask layer 212D, and (ii) a lower gate portion 212SL (FIG. 3B) having a second portion of polysilicon structure 212B. In some embodiments, the upper portion of polysilicon structure 212B, the nitride mask layer 212C, and the oxide mask layer 212D in each of the upper gate portions 212SU can have: (i) rectangular cross-sectional profiles along an X-axis, (ii) substantially linear sidewalls, and (iii) widths W1 of about 9 nm to about 12 nm. In some embodiments, the lower portion of polysilicon structure 212B in each of the lower gate portions 212SL can have: (i) a tapered cross-sectional profile (e.g., a V-shaped cross-sectional profile) along an X-axis, (ii) sloped sidewalls, (iii) an angle of about 70 degrees to about 80 degrees between the sloped sidewall and top surface of STI region 118, and (iv) width W2 of about 5 nm to about 8 nm in a middle region of the lower portion of polysilicon structure 212B. In some embodiments, each of the inner gate portions 212N can be disposed on and in contact with topmost nanostructured layer 106 of the superlattice structure 104. In some embodiments, each of the inner gate portions 212N can have: (i) a rectangular cross-sectional profile along an X-axis, (ii) substantially linear sidewalls, and (iii) width W1 of about 9 nm to about 12 nm.

In some embodiments, the deposition of oxide layer 212A can include exposing the structure of FIG. 1 to a precursor, such as tetraethylorthosilicate (TEOS), in a chemical vapor deposition (CVD) process at a temperature of about 650° C. to about 750° C. to deposit the oxide layer 212A (e.g., SiO₂) of about 2 nm to about 4 nm.

In some embodiments, after the first etch process, portions of the oxide layer 212A under outer gate portions 212S can be completely removed as shown in FIGS. 3 and 3A-3C, while portions of the oxide layer 212A at the interfaces between the polysilicon structure 212B and the superlattice structure 104 are retained to form IL layers 212A, as shown in FIGS. 3B and 3C. In some embodiments, during the first etch process the byproduct layer 224 is formed on the sacrificial gate structures 212 and exposed surfaces of the superlattice structure 104 and the STI regions 118, as shown in FIGS. 3 and 3A-3C. In some embodiments, the byproduct layer 224 can be formed as a result of etch byproducts produced from reactions between the etched off materials of the oxide layer 212A, the polysilicon layer 212B, the nitride mask layer 212C, the oxide mask layer 212D, and the gas mixture used in the first etch process. In some embodiments, the byproduct layer 224 can include silicon monoxide (SiO), a byproduct of SiO and chlorine (Cl), a byproduct of SiO and nitrogen (N), a byproduct of SiO and argon (Ar), and/or a product of SiO and hydrogen bromide (HBr).

In FIGS. 4 and 4A-4C, in some embodiments, after removal of the byproduct layer 224 during the second etch process, a gap 226 having a height H1 of about 2 nm to about 5 nm is formed between the polysilicon structure 212B and the STI region 118.

In some embodiments, the first etch process can include a plasma etch process using a gas mixture of an etch gas and a dilute carrier gas. In some embodiments, the etch gas can include Cl₂, HBr, difluoromethan (CH₂F₂), fluoroform (CHF₃), carbon tetrafluoride (CF₄), chlorodifluoromethane (CHClF₂), fluoromethan (CH₃F), hexafluorocyclobutene (C₄F₆), boron trichloride (BCl₃), sulfur hexafluoride (SF₆), or hydrogen (H₂). In some embodiments, the carrier gas can include an inert gas, such as Ar, N₂, helium (He), and neon (Ne). In addition, the gas mixture used in the plasma etch process can include a passivation gas. In some embodiments, the passivation gas can include N₂, O₂, CO₂, CH₄, SO₂, CO, and/or SiCl₄. The passivation gas can be used to vary the etch selectivity of the polysilicon layer 212B along the heights of the sacrificial gate structures 212 to achieve the cross-sectional profiles of polysilicon structures 212B of FIG. 3B having different widths (e.g., widths W1 and W2) along the heights of the polysilicon structures 212B. In some embodiments, the plasma etch process may be performed at a temperature of about 25 degrees Celsius to about 200 degrees Celsius under a pressure from about 1 mTorr to about 800 mTorr. The flow rate of the etch gas, the carrier gas, and the passivation gas can be about 20 standard cubic centimeters per minute (sccm) to about 3000 sccm. A plasma power of about 10 W to about 4000 W and a bias power of about 300 W to about 600 W can be used in the plasma etch process.

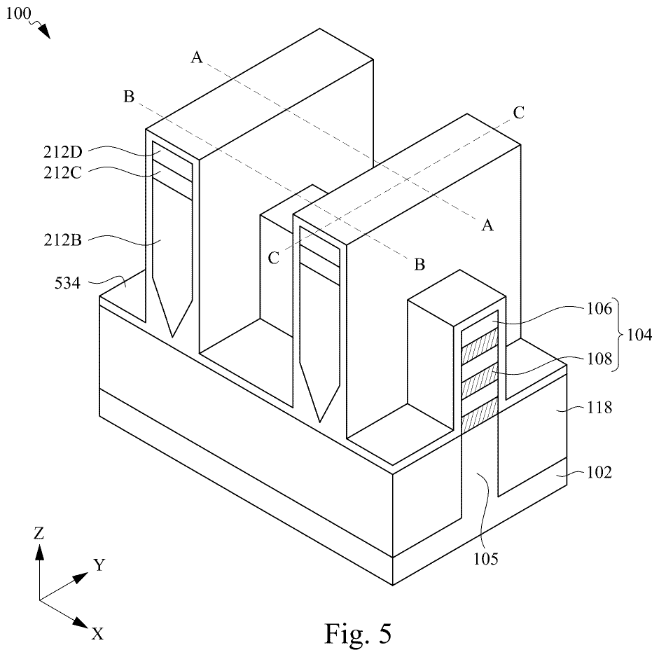

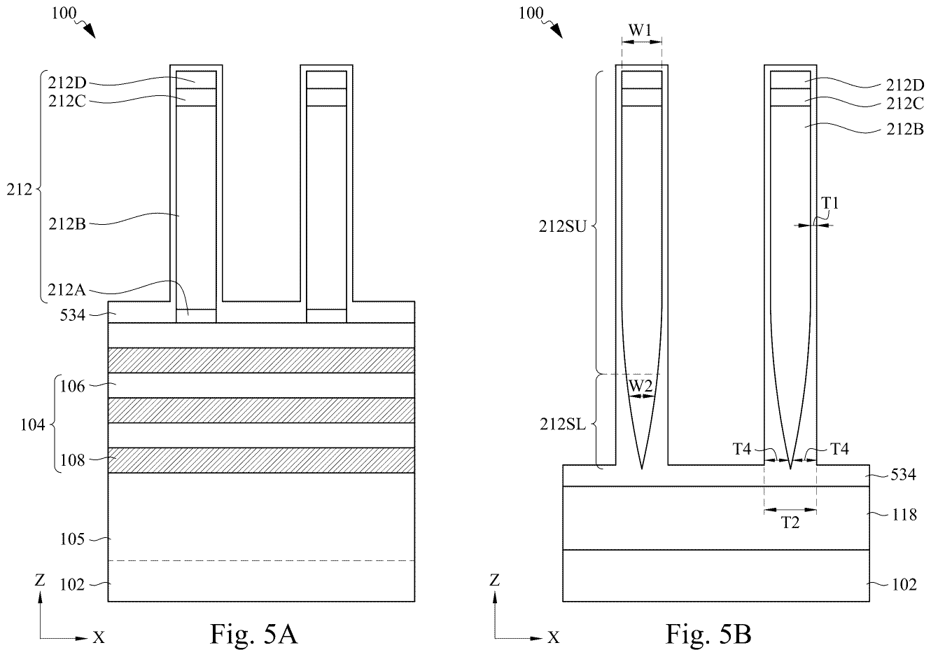

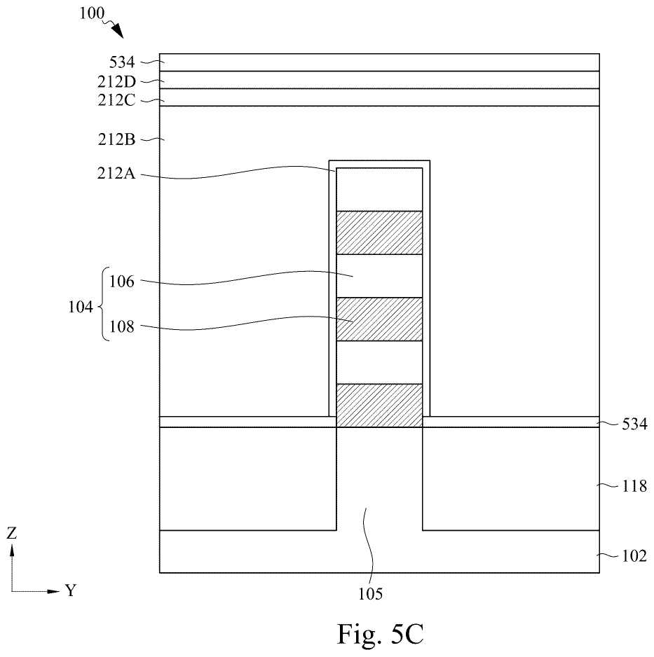

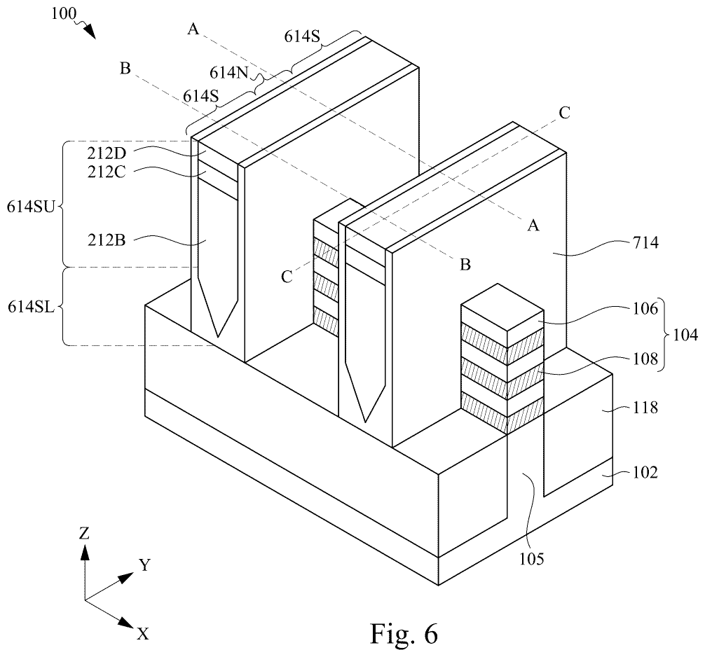

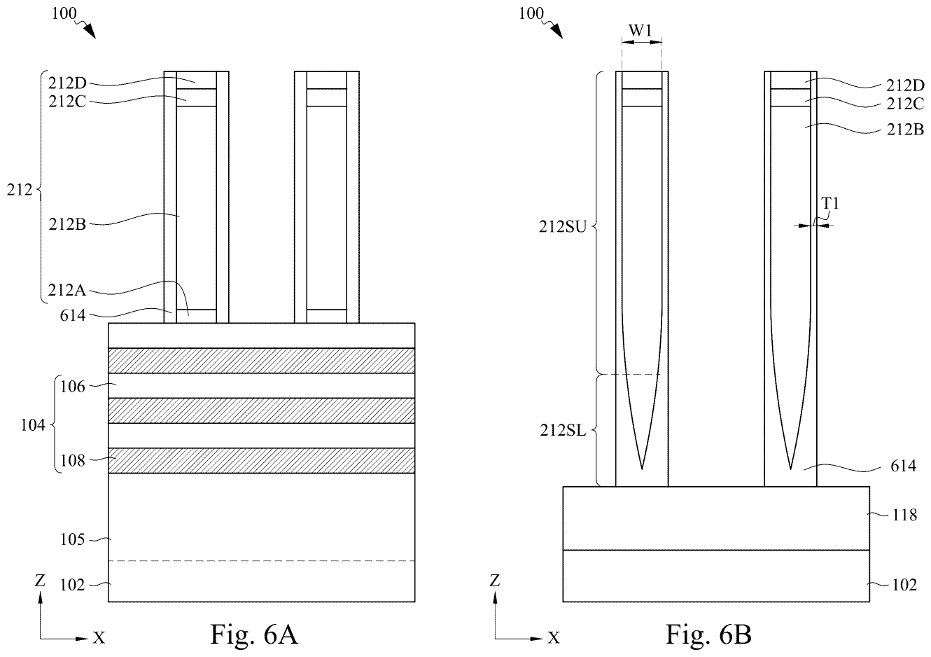

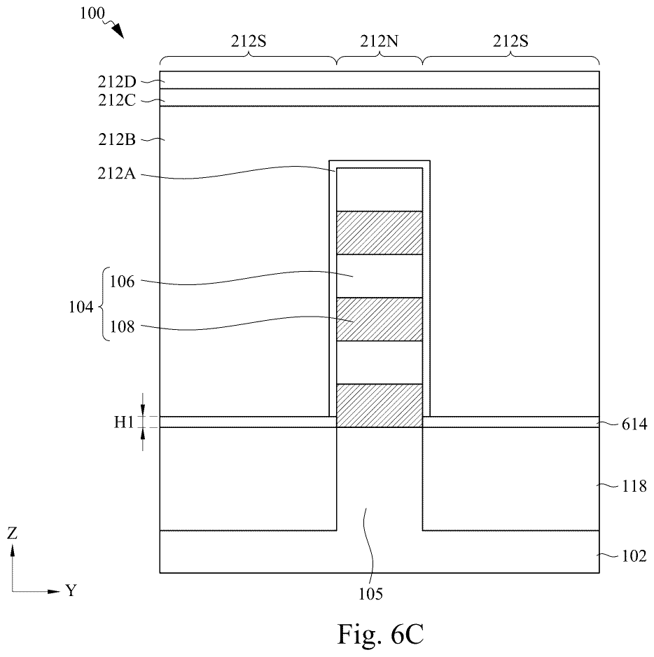

In FIGS. 5, 5A-5C, 6, and 6A-6C, after the byproduct layer 224 is removed, an outer gate spacer is formed on the sacrificial gate structure 212. For example, outer gate spacers 614 (FIGS. 6 and 6A-6C) are formed on the sacrificial gate structures 212. In some embodiments, the formation of outer gate spacers 614 can include sequential operations of: (i) depositing a dielectric layer 534 having the material of the outer gate spacers 614 on the structures of FIGS. 4 and 4A-4C, as shown in FIGS. 5 and 5A-5C, (ii) performing an anneal process to densify the dielectric layer 534, and (iii) performing an etch process on the densified dielectric layer 534 to form outer gate spacers 614 with structural profiles as shown in FIGS. 6 and 6A-6C.

In some embodiments, the dielectric layer 534 can be deposited in a plasma enhanced CVD (PECVD) process using a gas mixture of TEOS, H₂, ammonia (NH₃), N₂, and/or O₂ at a temperature of about 500 degrees Celsius to about 600 degrees Celsius. A plasma power of about 100 W to about 300 W and a bias power of about 200 W to about 500 W can be used in the PECVD process. In some embodiments, the bias applied to substrate 102 during the PECVD process can be controlled to vary the deposition selectivity of dielectric layer 534 along the heights of the sacrificial gate structures 212 to achieve the cross-sectional profile of the dielectric layer 534 of FIG. 5B having different thicknesses (e.g., thicknesses T1, T2, and T4) along the heights of the polysilicon structures 212B. In some embodiments, the dielectric layer 534 can have a thickness T1 surrounding the upper portions of polysilicon structures 212B in each of upper gate portions 212SU. In some embodiments, the dielectric layer 534 can have a thickness T4, greater than the thickness T1, surrounding the lower portions of the polysilicon structures 212B in lower gate portions 212SL, as shown in FIGS. 5 and 5B. In some embodiments, the dielectric layer 534 can have a thickness T2, greater than the thicknesses T1 and T4, surrounding the tips of the polysilicon structures 212B in lower gate portions 212SL, as shown in FIGS. 5 and 5B. In some embodiments, the bias applied to substrate 102 during the PECVD process can be controlled to fill the gap 226 (shown in FIGS. 4, 4B, and 4C) between the polysilicon structure 212B and the STI region 118, as shown in FIGS. 5B and 5C.

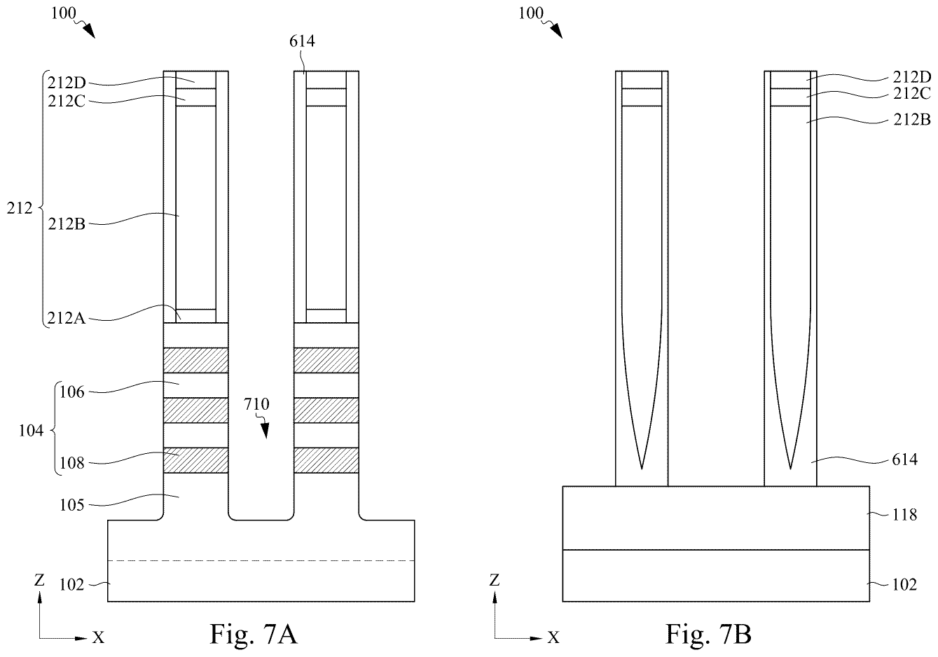

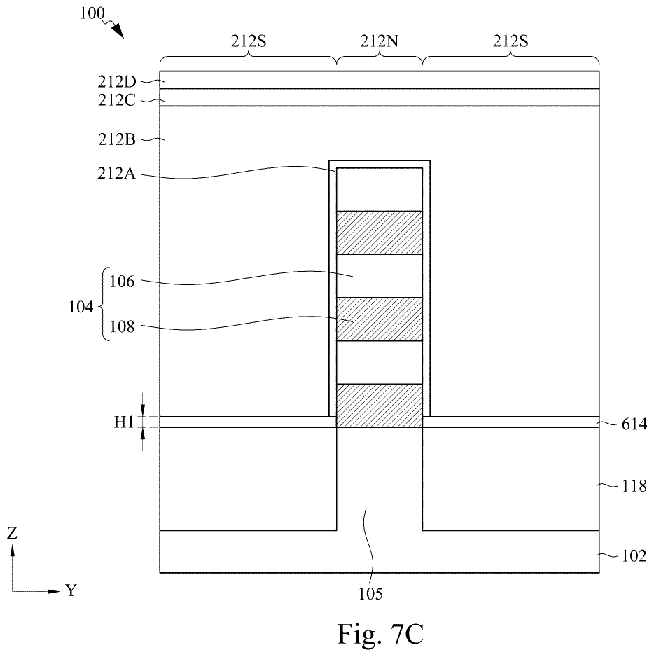

FIGS. 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, and 15C are cross-sectional side views of various stages of manufacturing the semiconductor device structure 100 taken along cross-section A-A, cross-section B-B, cross-section C-C of FIG. 6, in accordance with some embodiments. In FIG. 7A-7C, portions of the superlattice structure 104 that are not covered by the sacrificial gate structures 212 are removed to form source/drain (S/D) openings 710. The S/D openings 710 define S/D regions to be formed for the semiconductor device structure 100, which are located on opposite sides of each sacrificial gate structure 212. In some cases, some S/D regions may be shared between various transistors. For example, various S/D regions may be connected together and implemented as multiple functional transistors.

The S/D openings 710 may be formed by a cyclic process. As will be discussed below, the cyclic process is performed so that the S/D openings 710 (and thus subsequent epitaxial S/D features) are formed with a substantially straight vertical sidewall profile. The cyclic process may include a plurality of process cycles each process cycle comprising an etch step, a passivation step, and a treatment step. The etch step in each process cycle removes a portion of the nanostructured layers 106 and nanostructured sacrificial layers 108. The passivation step in each process cycle is configured to protect exposed surfaces of the S/D openings 710 from over-etching during subsequent etch process. The treatment step in each process cycle is configured to soften the previously formed passivation layer for easy removal at the subsequent etch step in the next process cycle. The cyclic process is performed until a desired depth of the S/D openings 710 is reached.

In some embodiments, the etch step is performed to remove the nanostructured layers 106 and nanostructured sacrificial layers 108, thereby forming the S/D openings 710 with a first depth. A portion of the STI regions 118 around the superlattice structure 104 may also be removed. The etch step may be a dry etch process, such as RIE, NBE, or any suitable anisotropic etch process. The etch step may be performed until the topmost nanostructured sacrificial layer 108 is etched through. In one exemplary embodiment, the etch step is a plasma etch process using a hydrocarbon-based etch chemistry, a bromine-based etch chemistry, a chlorine-based etch chemistry, a fluorine-based etch chemistry, or the like. Exemplary hydrocarbon-based etch chemistry may include methane (CH₄), ethane (C₂H₆), propane (C₃H₈), or the like, or a combination thereof. Exemplary bromine-based etch chemistry may include hydrogen bromide (HBr), bromine (Br₂), boron tribromide (BBr₃), or the like, or a combination thereof. Exemplary chlorine-based etch chemistry may include chlorine gas (Cl₂), chloroform (CHCl₃), carbon tetrachloride (CCl₄), boron trichloride (BCl₃), or the like, or a combination thereof. Exemplary fluorine-containing gas may include tetrafluoromethane (CF₄), hexafluoroethane (C₂F₆), octofluorocyclobutane (C₄F₈), hexafluorobutadiene (C₄F₆), sulfur hexafluoride (SF₆), nitrogen trifluoride (NF₃), difluoromethane (CH₂F₂), difluoroethane (C₂H₄F₂), trifluoromethane (CHF₃), hexafluoroethane (C₂F₆), or the like, or a combination thereof. A dilute gas, such as helium (He), nitrogen (N₂), or the like, may also be used in combination with the etch chemistries. An inert gas, such as argon (Ar), neon (Ne), krypton (Kr), or the like, may be provided with the etch chemistries to increase bombardment effect and thus, enhanced etch rates of the nanostructured layers 106 and nanostructured sacrificial layers 108.

In some embodiments, the plasma etch process may utilize a capacitively coupled plasma (CCP) source, an inductively coupled plasma (ICP) source, dipole antenna plasma source, a resonant antenna plasma source, an electron cyclotron resonance (ECR) plasma source, or glow discharge plasma (GDP) source driven by an RF power generator or a microwave plasma source using a tunable frequency ranging from about 2 MHz to about 2.45GHz, such as about 13.56 MHz. The process chamber may be operated at a pressure in a range of about 5 mTorr to about 20 mTorr and a temperature of about 20 degrees Celsius to about 240 degrees Celsius. The RF power generator is operated to provide a source power between about 100 W to about 300 W. A biasing power in a range of about 100 W to about 300 W is provided to a substrate support on which the semiconductor device structure 100 is disposed to provide etch directionality. The source power and the biasing power may be controlled so that the ion acceleration energy is between about 20 eV to about 200 eV. In some cases, a pulse plasma etch may be used. In such cases, the output of the power generator may be controlled by a pulse signal having a duty cycle in a range of about 5% to 95%. Alternatively, the plasma etch process may use a bias power only (with zero source power). In some embodiments, the plasma etch process may be performed in a plasma etch chamber with in-situ ALD capability. In one exemplary embodiment, the plasma etch process uses a plasma formed from a gas mixture containing CH₄, Cl₂, HBr, CHF₃, for example.

In some embodiments, the passivation step is performed to form a passivation layer on the exposed surfaces of the S/D openings 710. The passivation layer protects the exposed surfaces of the S/D openings 710 from over-etching in the lateral direction during the subsequent etch step. In some embodiments, the passivation layer may be configured to lower the etching selectivity of the exposed surfaces of the S/D openings 710 to the etchants used for subsequent etch process. A biasing power may be applied to the substrate support during the passivation step so that the majority of etch chemistries is directed towards the bottom of the S/D openings 710. Therefore, while the passivation layer at the sidewall and bottom surface of the S/D openings 710 is exposed to the etchants, the passivation layer at the bottom surface of the S/D openings 710 is removed at a faster rate than the rate of the passivation layer on the sidewall of the S/D openings 710. With this approach, the impact of the etchant on the sidewall of the S/D openings 710 is diminished by the passivation layer, allowing the S/D openings 710 to be extended vertically with a straight and symmetric sidewall profile during the subsequent etch step.

The passivation layer may be a dielectric material or an oxide-based passivation layer, such as SiO, SiON, SiN, SiO₂, or the like, or any combination thereof. In some embodiments, the passivation layer may be formed by exposing the exposed surfaces of the S/D openings 710 to a gas mixture comprising a silicon-containing precursor (e.g., SiCl₄), an oxygen-containing precursor (e.g., O₂), and/or a nitrogen-containing precursor (e.g., N₂). In some embodiments, a hydrogen halide such as hydrogen bromide (HBr) may be flowed along with the silicon-containing precursor and the oxygen-containing precursor. In some embodiments, the passivation layer is deposited by an in-situ ALD process in the same chamber as the plasma etch process used for the etch step. For example, an in-site ALD technique using precursors such as DIPAS (di(isopropylamino)silane) and BTBAS (bis(tertiary-butylamino)silane) in combination with Ar or O₂ plasma treatment to form a silicon-containing film. For example, the passivation layer may be formed by supplying a silicon-containing source gas, such as DIPAS or BTBAS, to the process chamber, supplying a plasma of a reactive gas, such as an oxygen-containing gas or a nitrogen-containing gas, to the process chamber. The radicals from the plasma of the reactive gas oxidize or nitride substances derived from the silicon-containing source gas to form the silicon-containing film.

In some embodiments, the passivation step may utilize the same plasma source as the etch step. The process chamber may be operated at a pressure in a range of about 5 mTorr to about 20 mTorr. The RF power generator is operated to provide a source power between about 100 W to about 300 W. A biasing power in a range of about 10 W to about 50 W is provided to the substrate support during the passivation step. In some embodiments, the source power used during the passivation step (e.g., 200 W to about 500 W) is greater than the etch step (e.g., 100 W to about 300 W), and the biasing power (e.g., 10 W to about 50 W) used during the passivation step is lower than the etch step (e.g., 100 W to about 300 W).

In some embodiments, the treatment step is performed to bombard and soften the passivation layer. The softened passivation layer allows its easy removal during the subsequent etch step at the next process cycle. The treatment step may be a bombardment process using plasma formed from hydrogen gas (H₂), N₂, Ar, or the like, or any combination thereof. In some embodiments, the treatment step uses neutral radical of species formed from a nitrogen-containing gas, a hydrogen-containing gas, or a combination thereof.

In some embodiments, the treatment step may utilize the same plasma source as the etch step. The process chamber may be operated at a pressure in a range of about 50 mTorr to about 100 mTorr. A biasing power is applied to the substrate support during the treatment step so that the majority of ions and/or radicals are directed towards the bottom of the S/D openings 710 for greater directionality. Higher directionality can also be achieved by lowering frequency for biasing power. In some embodiments, the source power (e.g., 50 W to about 100 W) used during the treatment step is less than that of the etch step (e.g., 100 W to about 300 W), and the biasing power (e.g., 200 W to about 400 W) used during the passivation step is greater than the etch step (e.g., 100 W to about 300 W).

The cyclic process discussed above may repeat two or more times until a desired depth of the S/D openings 710 is reached. In some embodiments, the total number of the process cycle may correspond to the number of the nanostructured sacrificial layers 108 in the superlattice structure 104. In any case, the S/D openings 710 as formed have a straight vertical sidewall profile with a substantially uniform critical dimension (CD) from top to bottom.

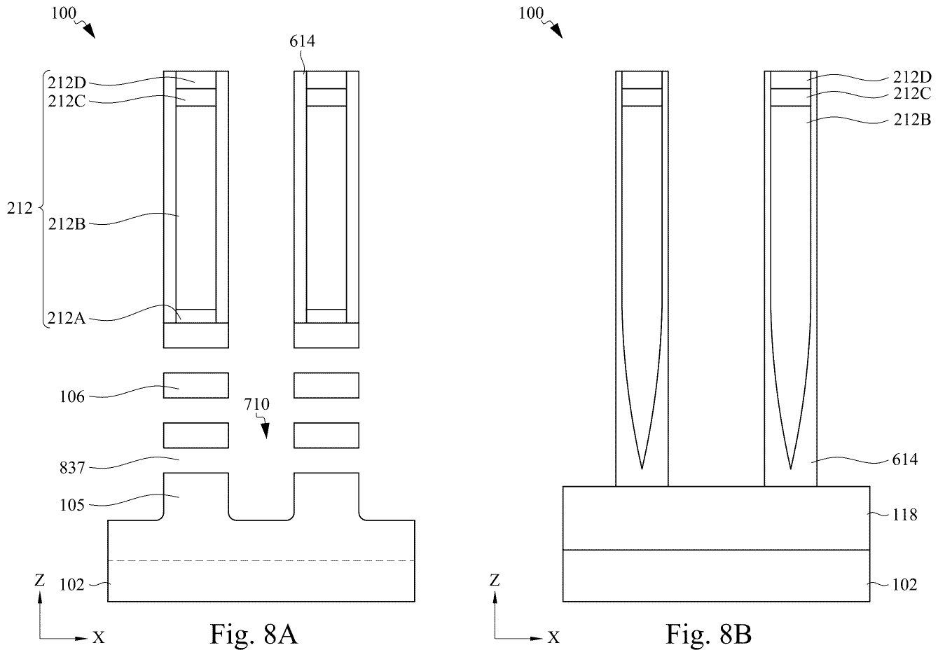

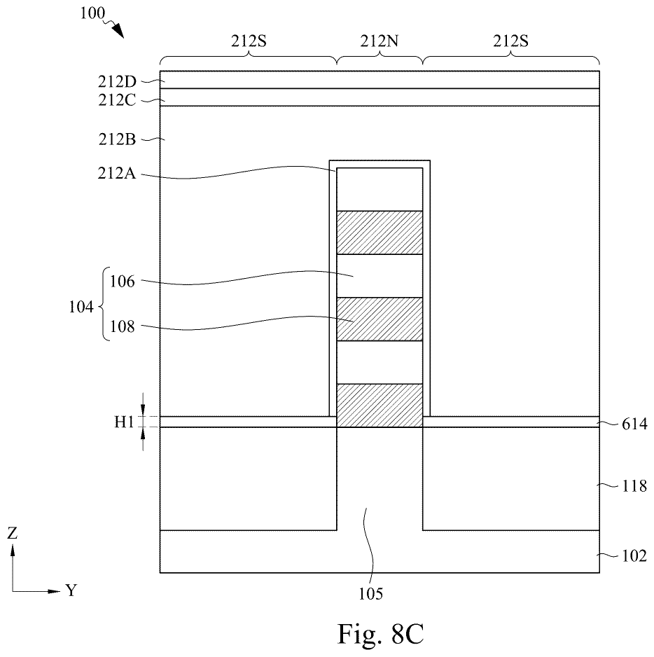

In FIG. 8A-8C, the nanostructured sacrificial layers 108 are removed. The removal of the nanostructured sacrificial layers 108 forms openings 837. The nanostructured sacrificial layers 108 may be removed by a selective etch process, such as a selective dry etch process, a selective wet etch process, or a combination thereof. The selective etch process does not substantially affect the outer gate spacers 614, the nanostructured layers 106, the sacrificial gate structures 212, and the substrate 102. In some embodiments, the selective etch process is a selective wet etching process. In cases where the nanostructured sacrificial layers 108 are made of SiGe and the nanostructured layers 106 are made of silicon, the nanostructured sacrificial layers 108 can be selectively etched using an etchant such as, but not limited to, ammonium hydroxide (NH₄OH), tetramethylammonium hydroxide (TMAH), ethylenediamine pyrocatechol (EDP), or potassium hydroxide (KOH) solutions.

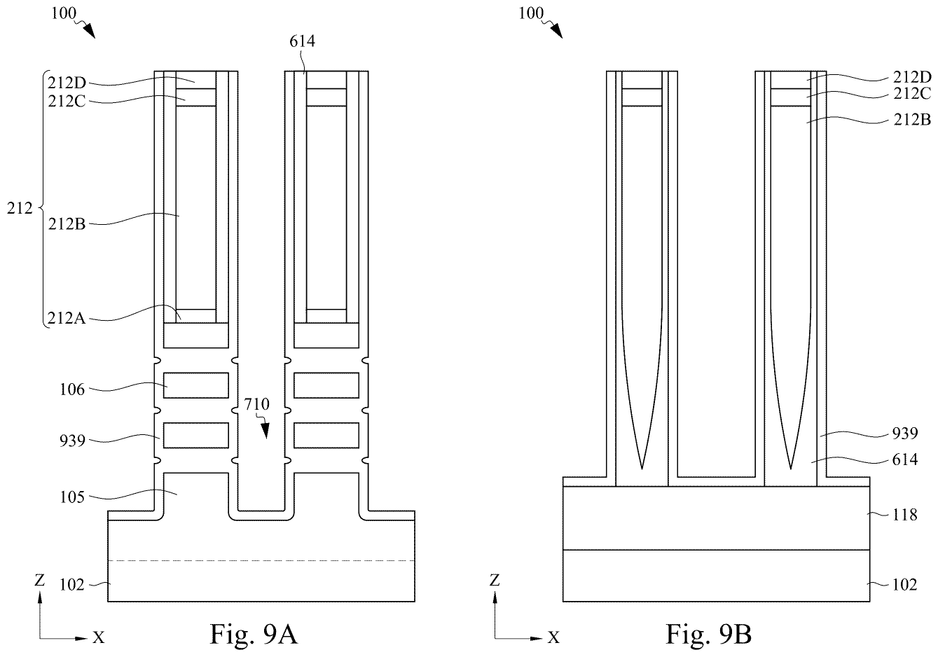

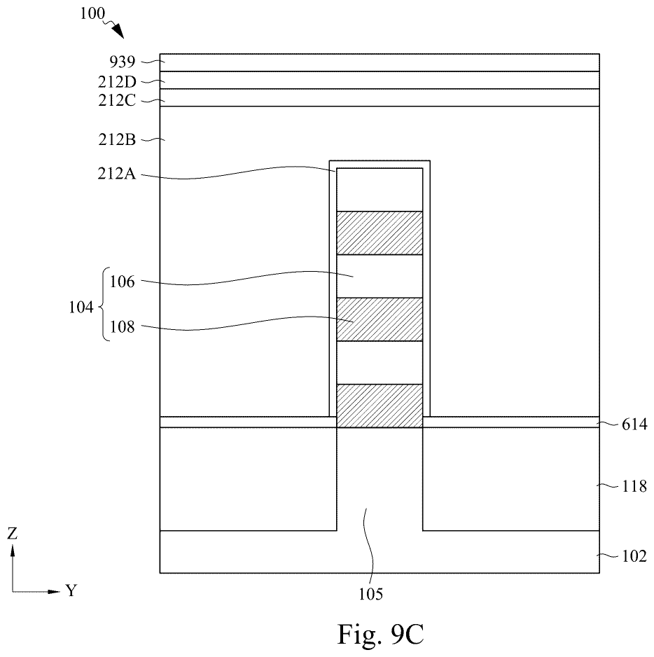

In FIGS. 9A-9C, a sacrificial dielectric material 939 is formed in the openings 837 (FIG. 8A) and on the exposed surfaces of the semiconductor device structure 100. In some embodiments, the sacrificial dielectric material 939 is an oxide formed by flowable chemical vapor deposition (FCVD) process. In some embodiments, the oxide is a carbon-containing silicon oxide. The use of the sacrificial dielectric material 939 helps to preserve surface profile of the nanostructured layers 106 during the subsequent sheet (or channel) formation stage. In traditional cases where the nanostructured sacrificial layers 108 include Ge and the nanostructured layers 106 include silicon, the Ge in the nanostructured sacrificial layers 108 may diffuse into and react with Si to form SiGe due to high temperature used during the formation of the subsequent S/D features 110. When the nanostructured sacrificial layers 108 are selectively removed during the sheet formation stage, a surface portion of the nanostructured layers 106, which is now SiGe due to prior reaction with Ge, will also be removed. The removal of the nanostructured sacrificial layers 108 therefore induces extra silicon loss (e.g., about 1.5 to 2.5 nm in thickness) in the surface portion of the nanostructured layers 106, resulting in thickness reduction and/or concave-like damage to the nanostructured layers 106. When the thickness of silicon nanosheet channel layers (i.e., nanostructured layers 106) is affected, the channel resistance (R_{ch}) of the nanosheet channel layers may increase and the ability of the nanosheet channel layers to conduct current flow (e.g., DC) may be reduced. By replacing the nanostructured sacrificial layers 108 with a sacrificial dielectric layer 939 prior to formation of S/D features 110, there is minimum reaction between the nanostructured layers 106 and the sacrificial dielectric layer 139 during the subsequent formation of the S/D features 110, and the sacrificial dielectric layer 939 can be removed with an enhanced etch selectivity over the nanostructured layers 106. Since the surface profile of the nanostructured layers 106 remains substantially intact during the sheet formation stage, the channel resistance of the nanosheet channel layers is not increased and the issues discussed herein are avoided.

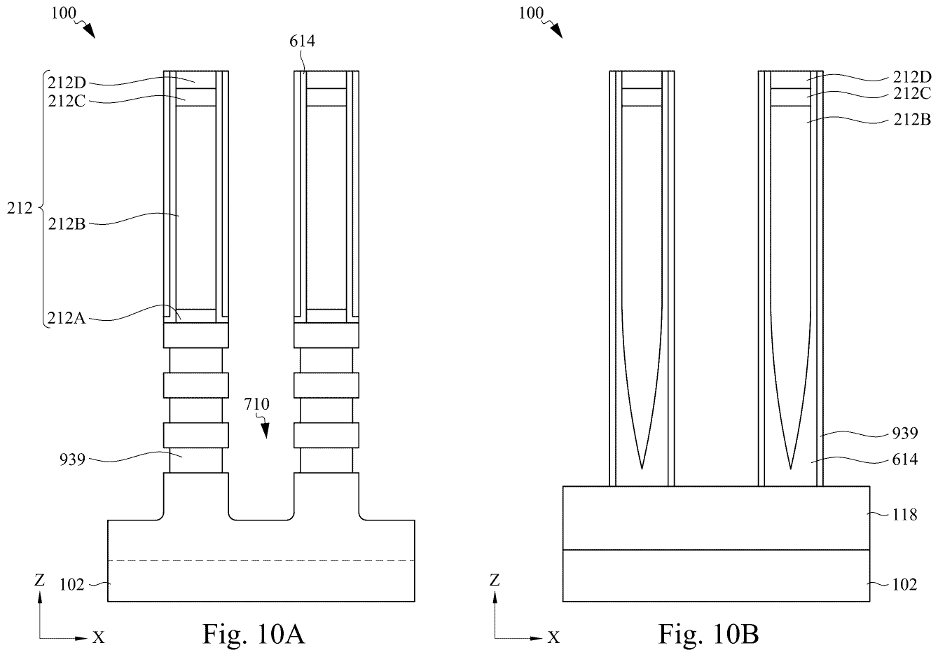

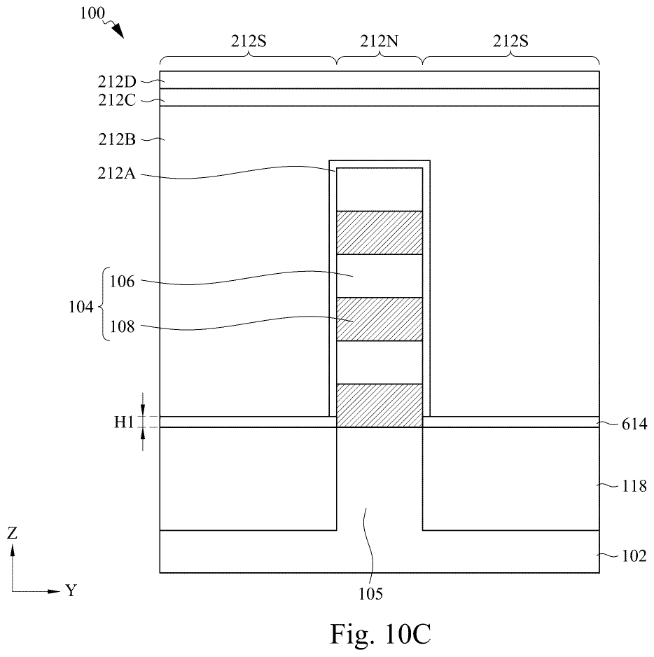

In FIGS. 10A-10C, an etch back process is performed to remove portions of the sacrificial dielectric layers 939 other than the portions of the sacrificial dielectric layers 939 formed in the openings 837 (FIG. 8A). In some embodiments, the etch back process is an anisotropic etching process. The etch back process may be a selective etch process that removes the sacrificial dielectric layers 939 but does not substantially affect the sacrificial gate structures 212, the outer gate spacers 614, the nanostructured layers 106, and the substrate 102. The selective etch process is performed until edge portions of each sacrificial dielectric layer 939 between the nanostructured layers 106 are removed. Therefore, the majority of the sacrificial dielectric layers 939 between the nanostructured layers 106 remains after the etch back process.

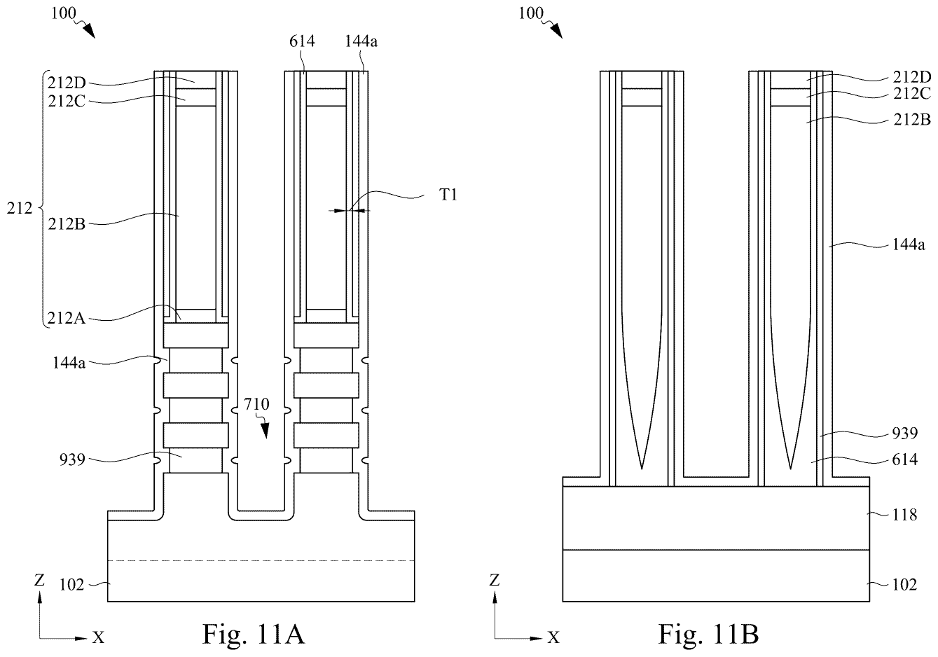

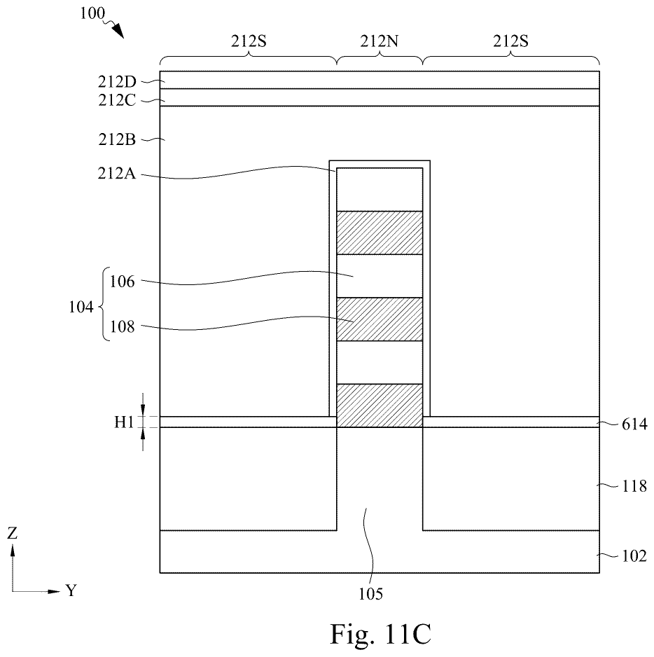

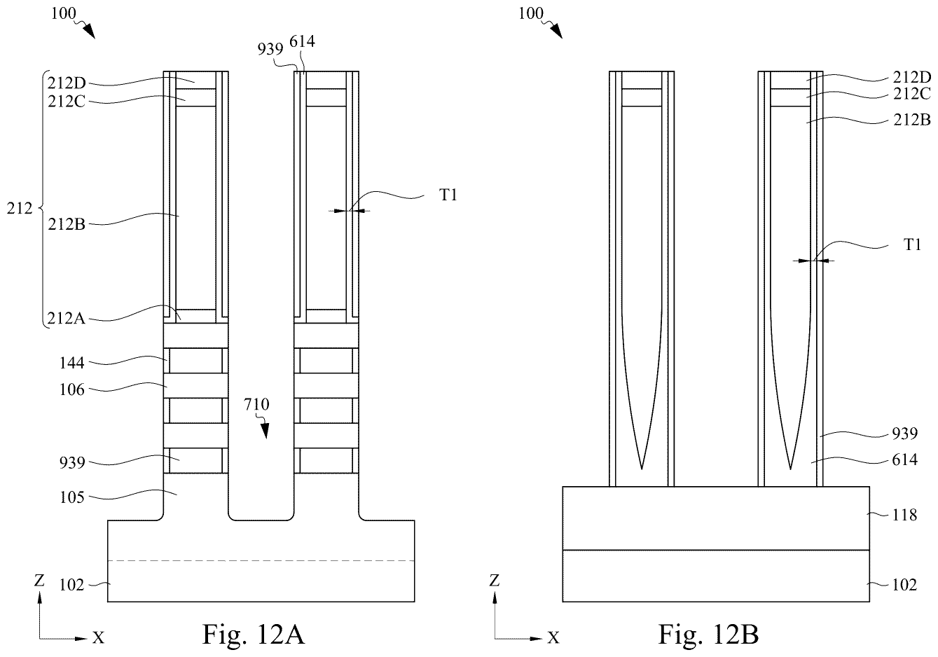

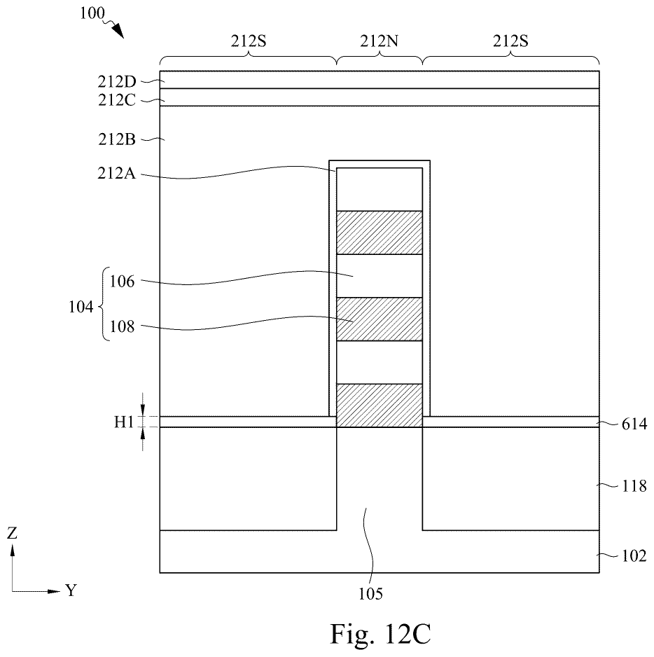

In FIGS. 11A-11C, after removing edge portions of the sacrificial dielectric material 939, a dielectric layer 144a is deposited in the cavities formed as a result of removal of the edge portions of the sacrificial dielectric layer 939. The dielectric layer 144a in the cavities forms dielectric spacers 144, as shown in FIG. 12A. The dielectric layer 144a may be made of a dielectric material, such as SiO₂, Si₃N₄, SiC, SiCP, SiON, SiOC, SiCN, SiOCN, and/or other suitable material. The dielectric layer 144a may be deposited as a conformal dielectric layer using a conformal deposition process, such as ALD.

In FIGS. 12A-12C, an anisotropic etching is performed to remove portions of the conformal dielectric layer 144a other than the dielectric layer 144a formed in the cavities. The dielectric layer 144a in the cavities forms dielectric spacers 144, and are protected by the nanostructured layers 106 during the anisotropic etching process. The sacrificial dielectric layer 939 is capped between the dielectric spacers 144 along the X direction. In some embodiments, the dielectric spacers 144 and the sacrificial dielectric material 939 include different materials having different etch selectivity.

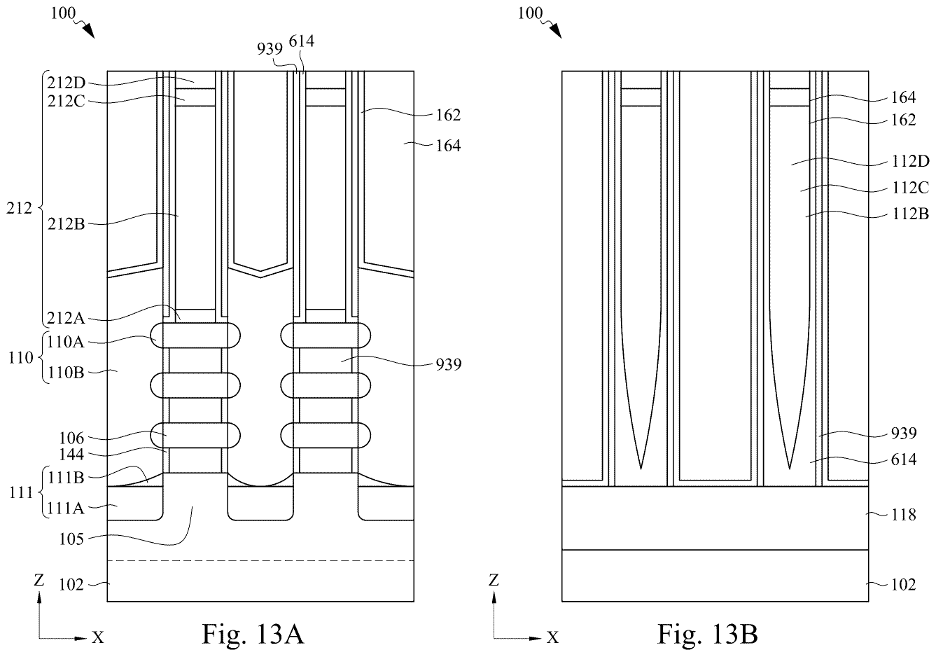

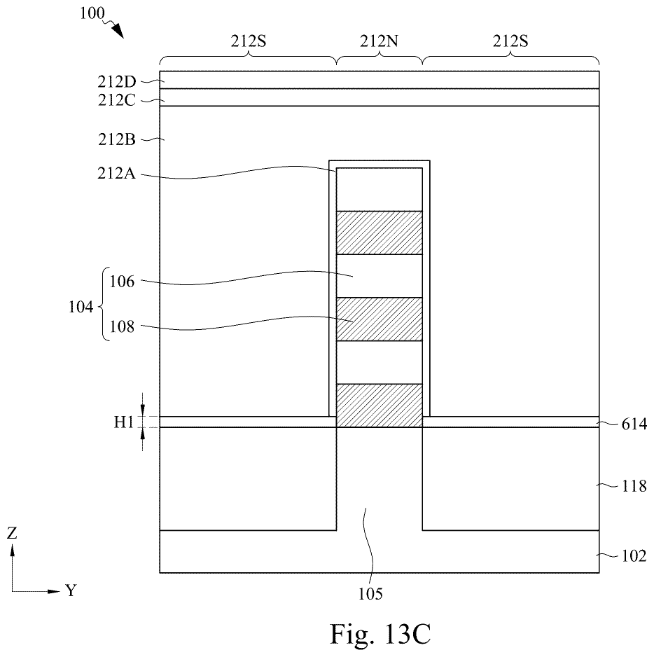

In FIGS. 13A-13C, isolation structures and S/D features are formed in the S/D openings 710. For example, isolation structures 111 and S/D features 110 are formed in S/D openings 710. In some embodiments, the formation of isolation structures 111 can include sequential operations of: (i) epitaxially growing an undoped silicon layer on the exposed surfaces of base structure 105 in S/D openings 710 to form undoped semiconductor layer 111A, as shown in FIG. 13A (not visible in cross-sectional views of FIGS. 13B and 13C), and (ii) forming dielectric layer 111B on undoped semiconductor layer 111A, as shown in FIG. 13A (not visible in cross-sectional views of FIGS. 13B and 13C). In some embodiments, the formation of S/D features 110 can include: (i) epitaxially growing S/D sub-features 110A on exposed surfaces of the nanostructured layers 106 and exposed surfaces (e.g., base structure 105) of the substrate 102, as shown in FIG. 13A (not visible in cross-sectional views of FIGS. 13B and 13C), and (ii) epitaxially growing S/D sub-features 110B on the S/D sub-features 110A, as shown in FIG. 13A. The S/D sub-features 110A are configured to promote epitaxial growth of subsequent S/D sub-features 110B. The formation of S/D features 110 is followed by the formation of contact etch stop layer (CESL) 162 and interlayer dielectric (ILD) layer 164, as shown in FIGS. 13A and 13B (not visible in cross-sectional view of FIG. 13C). After the ILD layer 164 is formed, a planarization operation, such as CMP, is performed on the semiconductor device structure 100 until the oxide mask layer 212D is exposed.

In some embodiments, the undoped semiconductor layer 111A can be disposed in the recessed region of base structure 105. In some embodiments, the undoped semiconductor layer 110A can include undoped silicon or other suitable undoped semiconductor material. In some embodiments, the dielectric layer 111B can be disposed directly on undoped semiconductor layer 111A and along sidewalls of the recessed region in base structure 105. In some embodiments, each dielectric layer 111B can include a nitride material, such as SiN, SiON, SiCON, and SiCN. In some embodiments, each dielectric layer 111B can include a silicon-rich dielectric material. In some embodiments, the silicon-rich dielectric material can include: (i) silicon-rich nitride (SiₓN_{y}) with a concentration of silicon atoms higher than the concentrations of nitrogen atoms, (ii) silicon-rich oxynitride (SiₓO_{y}N_{z}) with a concentration of silicon atoms higher than the concentrations of oxygen atoms and nitrogen atoms, (iii) silicon-rich oxycarbide (SiₓO_{y}C_{z}) with a concentration of silicon atoms higher than the concentrations of oxygen atoms and carbon atoms, (iv) silicon-rich oxycarbon nitride (Si_{w}OₓC_{y}N_{z}) with a concentration of silicon atoms higher than the concentrations of oxygen atoms, carbon atoms, and nitrogen atoms, (v) silicon-rich boron oxynitride (Si_{w}BₓO_{y}N_{z}) with a concentration of silicon atoms higher than the concentrations of oxygen atoms, boron atoms, and nitrogen atoms, (vi) silicon-rich boron oxycarbide (Si_{w}BₓO_{y}C_{z}) with a concentration of silicon atoms higher than the concentrations of oxygen atoms, boron atoms, and carbon atoms, or (vii) other suitable silicon-rich nitride-or carbide-based dielectric materials. The silicon-rich dielectric material of the dielectric layer 111B can provide a high etch resistance to the dielectric layer 111B during the formation of the dielectric layer 111B.

The S/D sub-features 110A may grow vertically and horizontally to form facets, which may correspond to crystalline planes of the material used for the nanostructured layers 106. In some cases, the S/D features 110 of a fin structure may grow and merge with the S/D features 110 of the neighboring fin structures. In any case, the S/D features 110 are formed with a substantially uniform CD from top to bottom. The S/D feature 110 may include one or more layers of Si, SiP, SiC and SiCP for an n-type FET or Si, SiGe, Ge for a p-type FET. The S/D features 110 may be formed by an epitaxial growth method using selective epitaxial growth (SEG), CVD, ALD or MBE. The nanostructured sacrificial layers 108 under the sacrificial gate structure 212 are separated from the S/D features 110 by the dielectric spacers 144.

It is contemplated that one of a pair of S/D features 110 located on one side of the sacrificial gate structures 212 may be a source region, and the other of the pair of S/D features 110 located on the other side of the sacrificial gate structures 212 may be a drain region. A pair of S/D features 110 includes a source feature and a drain epitaxial feature connected by the channels (i.e., the nanostructured layers 106). Source/drain region(s) may refer to a source or a drain, individually or collectively dependent upon the context. In this disclosure, a source and a drain are interchangeably used, and the structures thereof are substantially the same.

In some embodiments, the S/D sub-features 110A include silicon. In some embodiments, the S/D sub-features 110A include silicon and n-type or p-type dopants, depending on the conductivity type of the S/D features 110 to be grown thereon. The S/D sub-features 110A may be formed using selective epitaxial growth (SEG), ALD, MBE, or any suitable growth process. In some embodiments, the nanostructured layers 106 may be exposed to silicon-containing precursor(s) and n-type or p-type dopant-containing precursor(s) in a process chamber to form the S/D sub-features 110A. Once the predetermined volume of the S/D sub-features 110A is reached, the flow of the n-type or p-type dopant-containing precursor(s) may be terminated and group IV or group V precursor(s) are introduced into the process chamber along with the silicon-containing precursor(S) to form the S/D sub-features 110B.

In some embodiments, for p-type GAA FET, the S/D sub-features 110A can include epitaxially-grown Si without any Ge atoms and S/D sub-features 110B can include epitaxially-grown SiGe. In some embodiments, the S/D sub-features 110B can include a Ge atom concentration of about 45 atomic % to about 60 atomic % with any remaining atomic % being Si atoms. In some embodiments, for p-type GAA FET, S/D sub-features 110A and 110B can differ from each other based on p-type dopant (e.g., boron atoms) concentrations. For example, the S/D sub-features 110B can have a p-type dopant concentration higher than that in the S/D sub-features 110A. In some embodiments, the S/D sub-features 110A can be undoped. In some embodiments, the S/D sub-features 110B can include a boron dopant concentration of about 8×10²⁰ atoms/cm³ to about 3×10²¹ atoms/cm³.

The CESL 162 may include an oxygen-containing material or a nitrogen-containing material, and may be formed by CVD, PECVD, ALD, or any suitable deposition technique. The materials for the ILD layer 164 may include compounds comprising Si, O, C, and/or H, such as silicon oxide, TEOS oxide, SiCOH and SiOC.

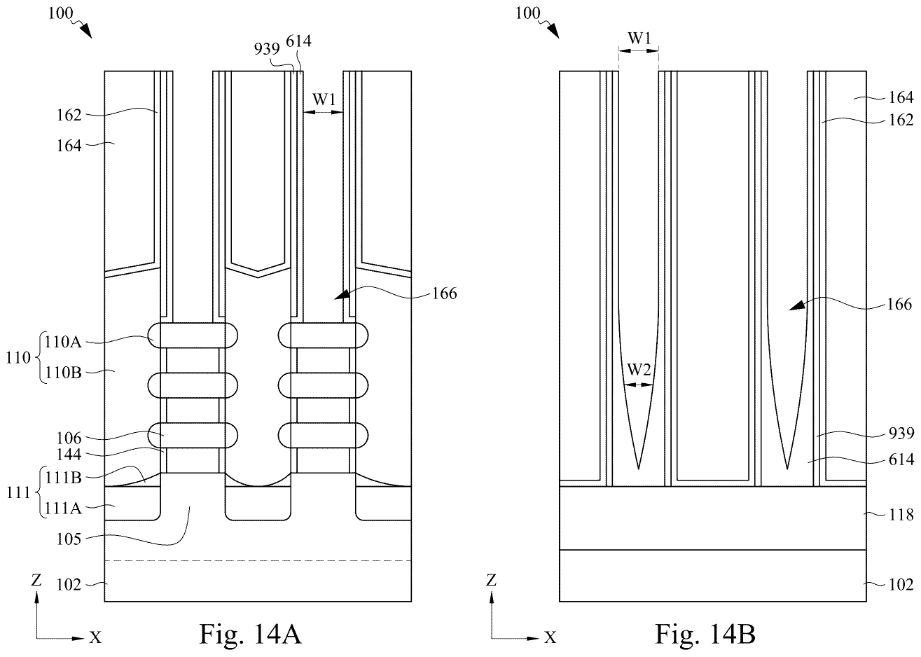

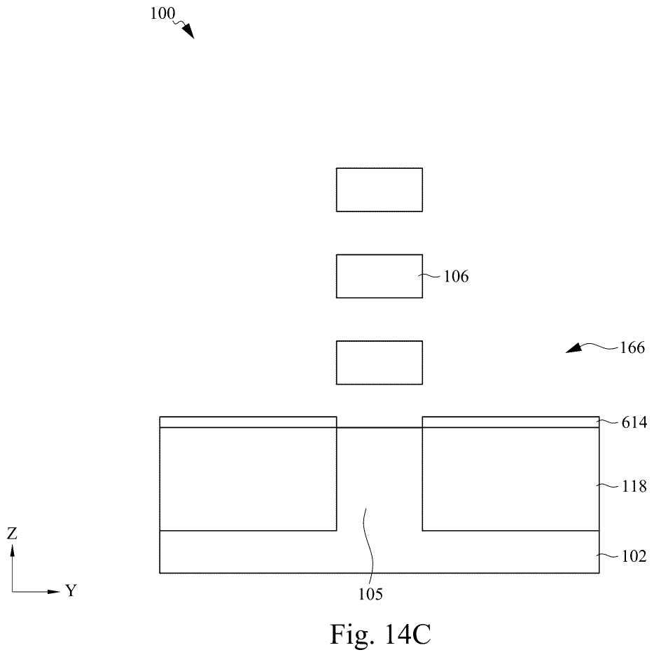

In FIGS. 14A-14C, the sacrificial gate structure and the sacrificial dielectric layers are removed (i.e., sheet formation stage). For example, the sacrificial gate structures 212 and sacrificial dielectric layers 939 are removed, which forms gate openings 166 between the nanostructured layers 106. The sacrificial gate structures 212 can be removed using plasma dry etching and/or wet etching. The sacrificial dielectric layers 939 disposed between the nanostructured layers 106 help preserve the integrity and surface profile of the nanostructured layers 106 during the sheet formation stage since the sacrificial dielectric layers 939 do not react or intermix with the nanostructured layers 106 in prior high temperature process of the S/D features 110. Therefore, the sacrificial dielectric layers 939 can be removed without damaging the nanostructured layers 106 during the sheet formation stage.

In some embodiments, the cross-sectional profiles of gate openings 166 on STI region 118, as shown in FIG. 14A, can be similar to the cross-sectional profiles of polysilicon structures 212B. Due to the tapered cross-sectional profiles of polysilicon structures 212B, less volume of polysilicon structures 212B are removed near the STI regions 118 compared to the volume removed for polysilicon structures with non-tapered cross-sectional profiles in other GAA FETS. As a result, polysilicon structures 212B are not over-etched to ensure complete removal of polysilicon structures 212B. Over-etching of non-tapered polysilicon structures can lead to formation of extended trenches in base structure 105, which increases parasitic capacitance in GAA FETs, as discussed above. Thus, due to the tapered cross-sectional profiles of polysilicon structures 212B and also due to the lower portions of polysilicon structures 212B being separated from STI regions 118 by the outer gate spacers 614, gate openings 166 can be prevented from extending into the STI regions 118 and base structure 105 during the etching of sacrificial gate structures 212.

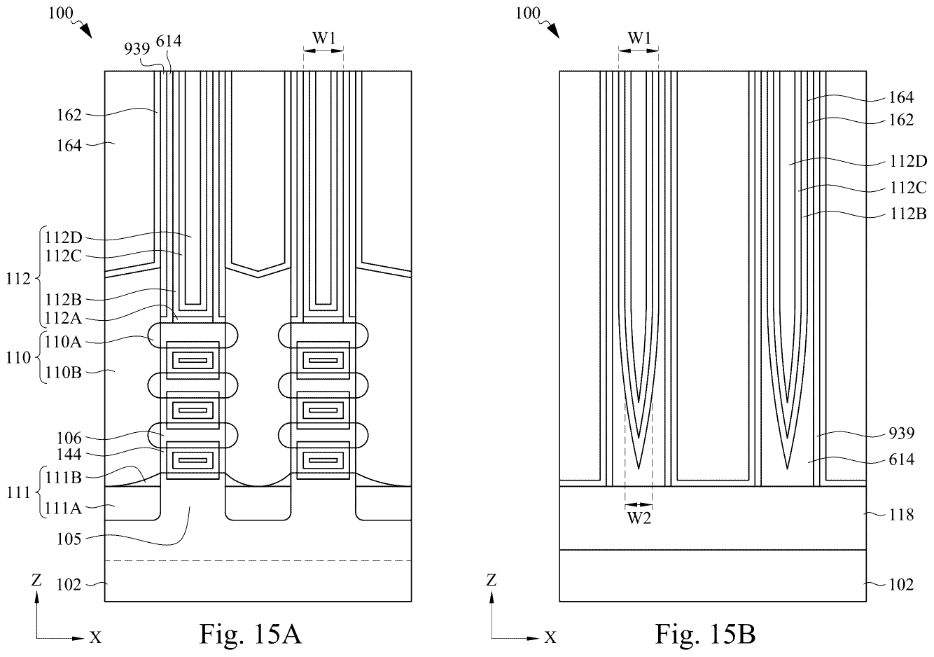

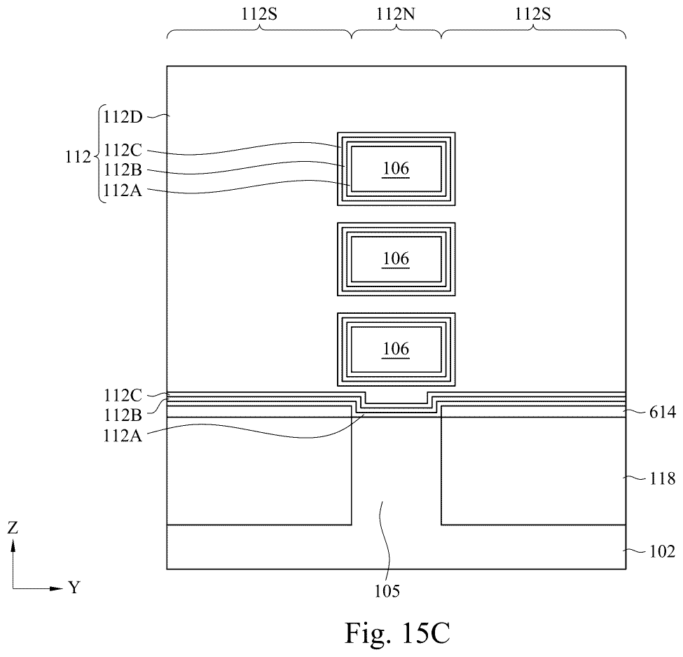

In FIGS. 15A-15C, replacement gate structures are formed in the gate openings. For example, GAA structures 112 are formed in the gate openings 166. The formation of GAA structures 112 can include sequential operations of: (i) performing an oxidation process on the exposed regions of nanostructured layers 106 in the gate openings 166 to form IL layers 112A, as shown in FIGS. 15A and 15C (not visible in cross-sectional view of FIG. 15B), (ii) forming HK gate dielectric layers 112B on IL layers 112A, (iii) forming WFM layers 112C on HK gate dielectric layers 112B, and (iv) forming gate metal fill layers 112D on WFM layers 112C.

The IL layers 112A may include or be made of an oxide (e.g., silicon oxide) formed by thermal or chemical oxidation of the nanostructured layers 106, a nitride (e.g., silicon nitride, silicon oxynitride, oxynitride, etc.), and/or a dielectric layer (e.g., hafnium silicate). The HK gate dielectric layers 112B may include or made of a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂). The HK gate dielectric layers 112B may be a conformal layer formed by a conformal process, such as an ALD process, a PECVD process, a molecular-beam deposition (MBD) process, or the like, or a combination thereof. The WFM layers 112C can include substantially Al-free Ti-based or Ta-based nitrides or alloys, such as titanium nitride (TiN), titanium silicon nitride (TiSiN), titanium gold (Ti-Au) alloy, titanium copper (Ti-Cu) alloy, tantalum nitride (TaN), tantalum silicon nitride (TaSiN), tantalum gold (Ta-Au) alloy, and tantalum copper (Ta-Cu) for p-type GAA FET. In some embodiments, the WFM layer 112C can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type GAA FET. The gate metal fill layer 112D can include a suitable conductive material, such as tungsten (W), titanium (Ti), silver (Ag), ruthenium (Ru), molybdenum (Mo), copper (Cu), cobalt (Co), Al, iridium (Ir), nickel (Ni), metal alloys, and a combination thereof.

Portions of the IL layers 112A, HK gate dielectric layers 112B, WFM layers 112C, and (iv) gate metal fill layers 112D may be removed by a planarization process, such as by a CMP process. After the CMP process, the top surfaces of the CESL 162, the ILD layer 164, the IL layers 112A, HK gate dielectric layers 112B, WFM layers 112C, and gate metal fill layers 112D are substantially co-planar.

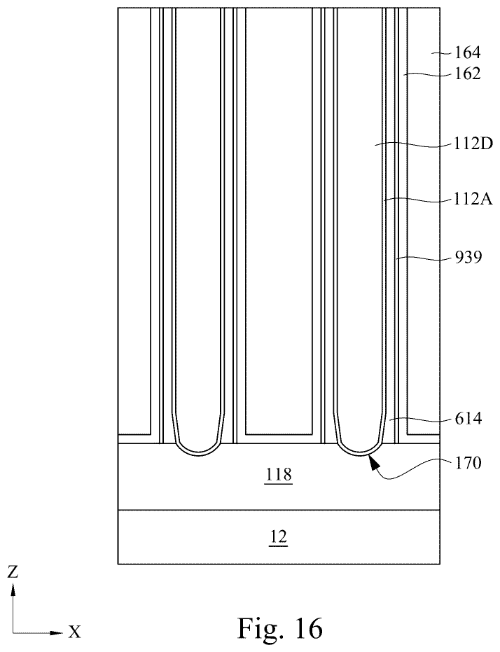

FIG. 16 illustrates a cross-section view of the semiconductor device structure 100 taken along cross-section B-B of FIG. 2 in accordance with some alternative embodiments. In this embodiment, unlike the sacrificial gate structures 212 of the embodiment of FIG. 4 in which the lower portion of polysilicon structure 212B in the lower gate portions 212SL is formed to have a tapered cross-sectional profile, the lower portion of the polysilicon structure 212B is formed to have a rectangular cross-sectional profile along an X-axis. During the formation of the replacement gate structure, the gate openings are etched so that the top surface of the STI region 118 has a slightly rounding shape 170. In this approach, the bottom gate portion does not extend too far into the base structure during the formation of the GAA structure in a gate replacement process. As a result, the spacing between the bottom gate portion and the S/D features is increased, which minimizes the parasitic capacitance in the GAA FET and improves the reliability and performance of the GAA FET.

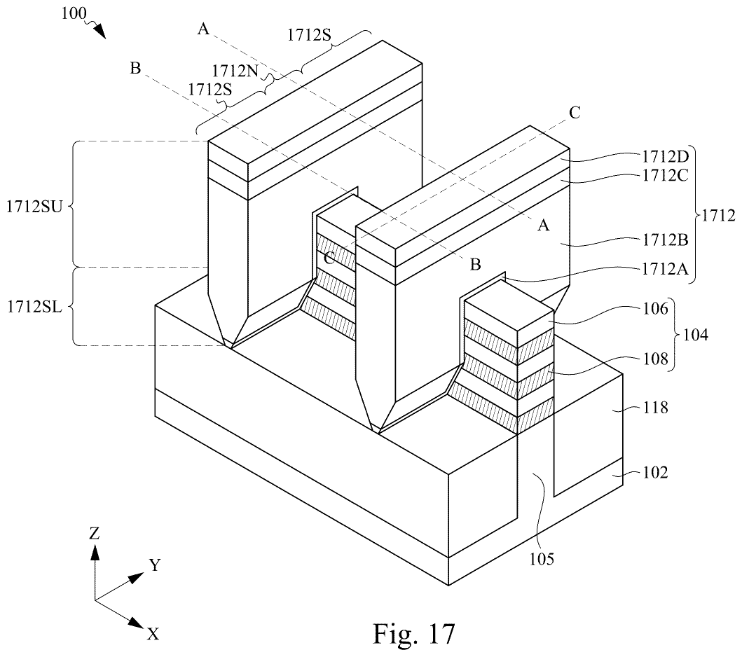

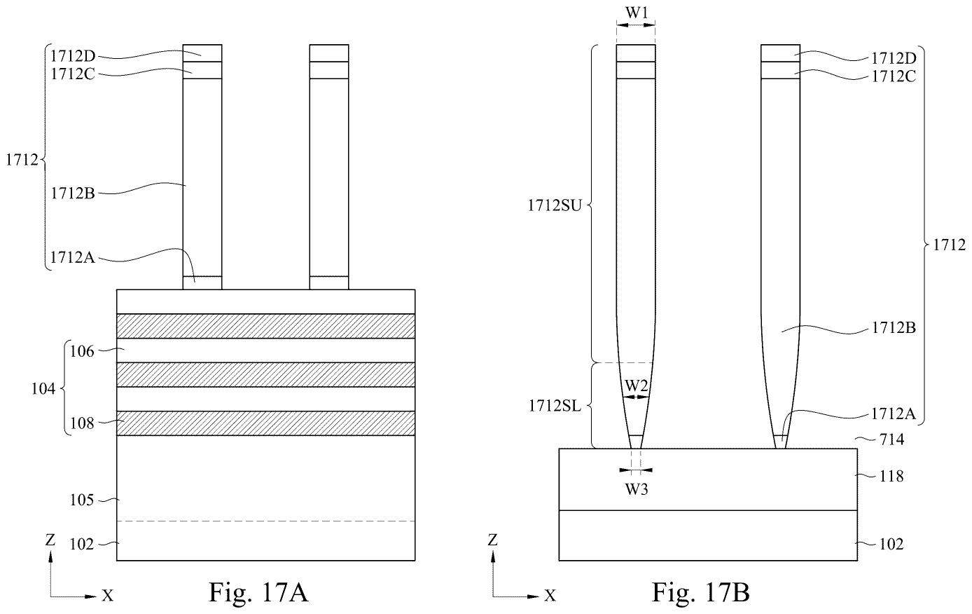

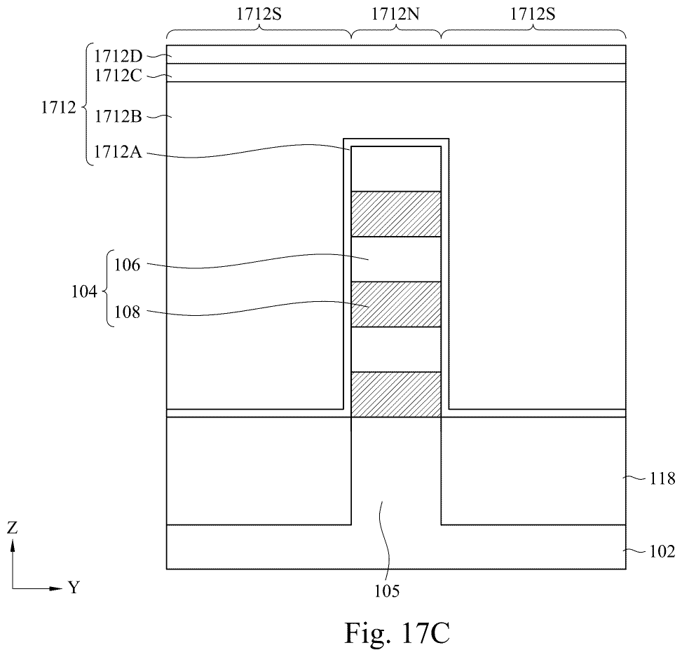

In FIGS. 17, 17A, 17B, and 17C, a semiconductor device structure similar to the semiconductor device structure 100 shown in FIG. 3 is formed. Specifically, a sacrificial gate structure with a first portion directly on the superlattice structure and a second portion directly on the STI region is formed. A sacrificial gate structure 1712 with outer gate portions 1712S directly on STI regions 118 and inner gate portion 1712N on superlattice structure 104 are formed. In some embodiments, the formation of sacrificial gate structure 1712 can include sequential operations of: (i) depositing oxide layer 1712A substantially conformally on STI regions 118 and superlattice structure 104, (ii) depositing amorphous, polycrystalline, or monocrystalline polysilicon layer 1712B on oxide layer 1712A, (iii) depositing nitride mask layer 1712C on polysilicon layer 1712B, (iv) depositing oxide mask layer 1712D on nitride mask layer 1712C, (v) performing the lithographic patterning process (not shown) on the structures, (vi) performing the first etch process on the structures to form sacrificial gate structures 1712 having IL layers 1712A, polysilicon structures 1712B, nitride layers 1712C, and oxide layers 1712D, and a byproduct layer 1724, and (vii) performing the second etch process using HF acid gas or solution on the structures to remove byproduct layer 1724 and form sacrificial gate structures 1712 with outer gate portions 1712S directly on STI regions 118 and inner gate portion 1712N directly on superlattice structure 104.

In some embodiments, each of outer gate portions 1712S can have: (i) an upper gate portion 1712SU having a first portion of polysilicon structure 1712B, nitride layer 1712C, and oxide layer 1712D, and (ii) a lower gate portion 1712SL having a second portion of polysilicon structure 1712B. In some embodiments, the upper portion of polysilicon structure 1712B, nitride layer 1712C, and oxide layer 1712D in each of upper gate portions 1712SU can have: (i) rectangular cross-sectional profiles along an X-axis, (ii) substantially linear sidewalls, and (iii) widths W1 of about 9 nm to about 12 nm. In some embodiments, the lower portion of polysilicon structure 1712B in each of lower gate portions 1712SL can have: (i) a tapered cross-sectional profile along an X-axis, (ii) sloped sidewalls, (iii) an angle of about 70 degrees to about 80 degrees between the sloped sidewall and top surface of STI region 118, (iv) a substantially linear bottom surface 1712BS in contact with top surface of STI region 118, (v) width W2 of about 5 nm to about 8 nm in a middle region of lower gate portion 1712SL, and (vi) width W3 of about 0 nm to about 3 nm of bottom surface 1712BS. In some embodiments, each of inner gate portions 1712N can be disposed on and in contact with topmost nanostructured layer 106 of superlattice structure 104. In some embodiments, each of inner gate portions 1712N can have: (i) a rectangular cross-sectional profile along an X-axis, (ii) substantially linear sidewalls, and (iii) width W1 of about 9 nm to about 12 nm.

In some embodiments, a portion of the outer gate spacer (e.g., the lower gate portion 1712SL) is in contact with sidewalls of the oxide layer 1712A.

In the embodiment shown in FIGS. 17 and 17A-17C, unlike the embodiment shown in FIGS. 4 and 4A-4C, portions of oxide layer 1712A are retained at the interfaces between polysilicon structures 1712B and STI regions 118 and between polysilicon structures 1712B and superlattice structure 104 to form IL layers 1712A after the first etch process. In some embodiments, similar to byproduct layer 224, a byproduct layer (not shown) can be formed on sacrificial gate structures 1712 and exposed surfaces of superlattice structure 104 and STI regions 118 during the first etch process. The first etch process used in forming the sacrificial gate structures 1712 can be similar to the first etch process used in forming the sacrificial gate structures 212, except the etching duration used in forming the sacrificial gate structures 1712 is shorter than in the first etch process used in forming the sacrificial gate structures 212.

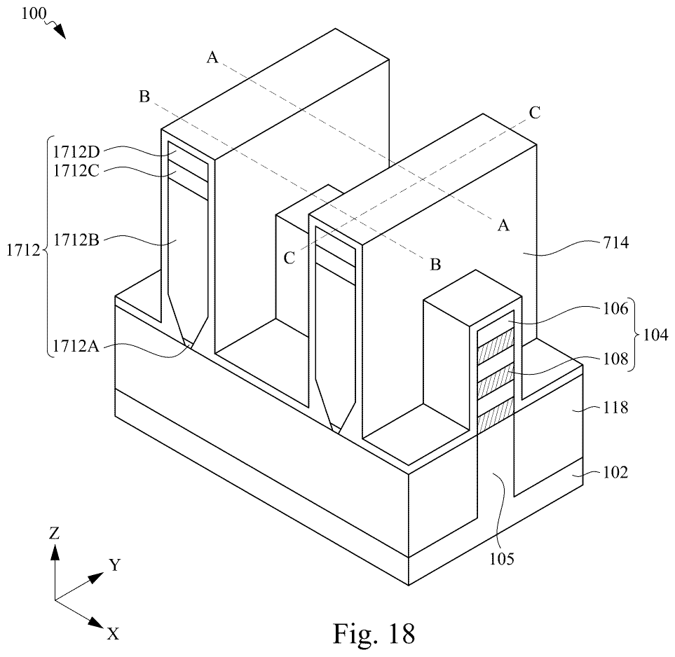

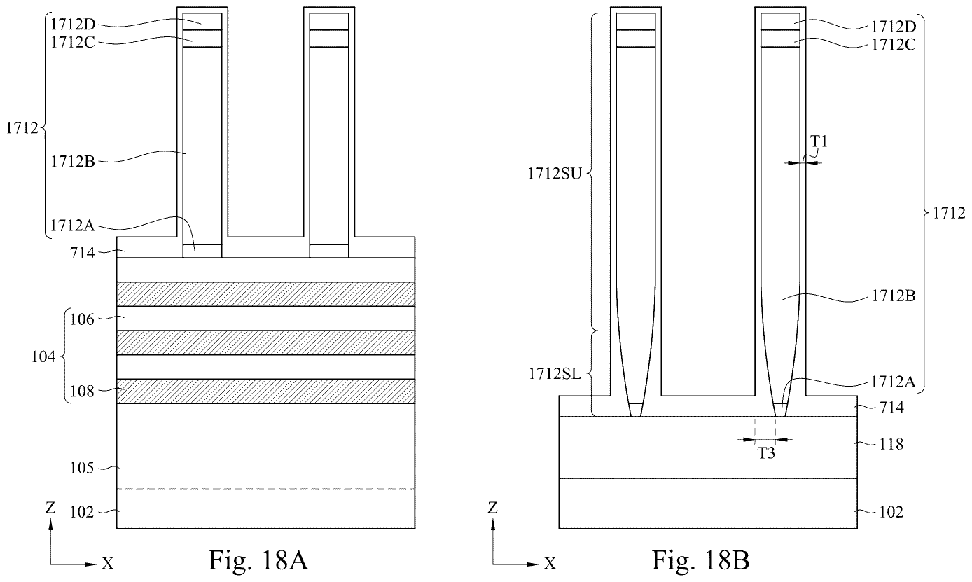

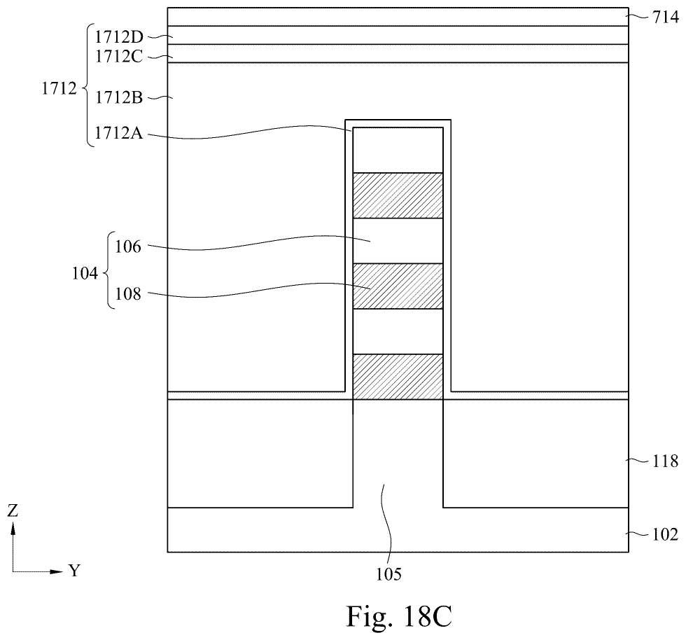

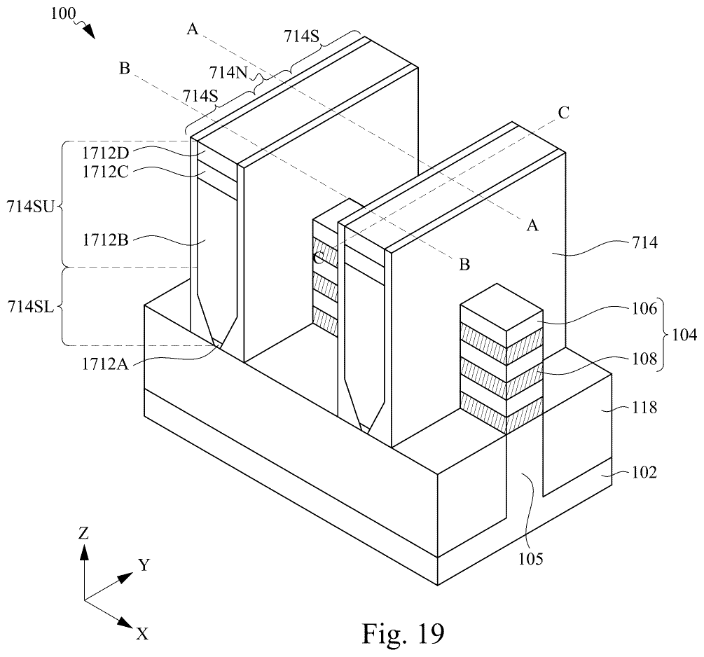

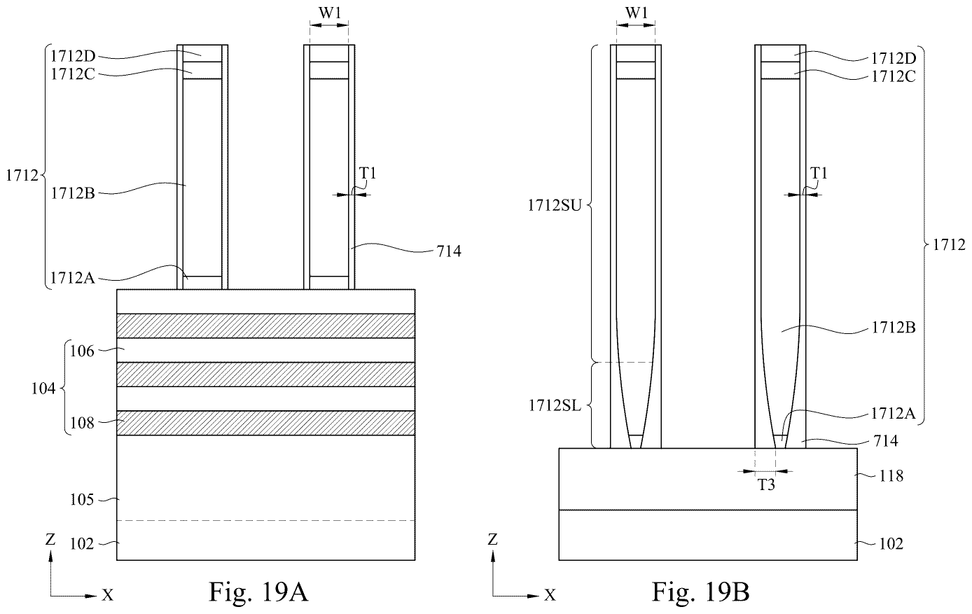

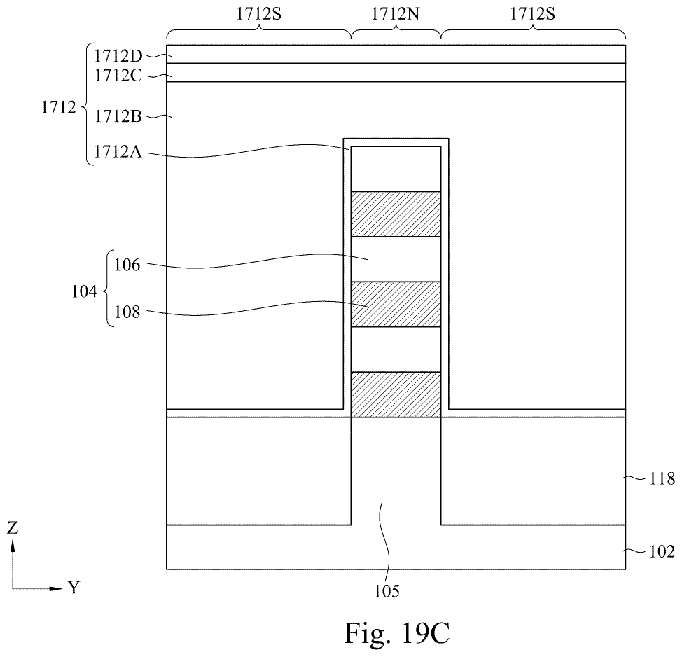

In FIGS. 18, 18A, 18B, 18C, 19, 19A, 19B, and 19C, outer gate spacers are formed on sidewalls of the sacrificial gate structure. For example, outer gate spacers 714 are formed on sidewalls of sacrificial gate structure 1712. In some embodiments, the formation of outer gate spacers 714 can include sequential operations of: (i) depositing a dielectric layer having the material of outer gate spacers 714 on the structures as shown in FIG. 18, (ii) performing an anneal process to densify the dielectric layer, and (iii) performing an etch process on the densified dielectric layer to form outer gate spacers 714 with structural profiles as shown in FIGS. 19 and 19A-19C. The outer gate spacers 714 can be formed by a process similar to the outer gate spacers 614 as discussed above. The outer gate spacer 714 may be formed so that the cross-sectional profile of dielectric layer has different thicknesses along the heights of polysilicon structures 1712B. In some embodiments, the outer gate spacers 714 can have thickness T1 surrounding the upper portions of polysilicon structures 1712B in upper gate portions 1712SU, as shown in FIG. 18C. In some embodiments, the outer gate spacers 714 can have a thickness T3, greater than thickness T1, surrounding the lower portions of polysilicon structures 1712B in lower gate portions 1712SL, as shown in FIGS. 18A and 18C.

In some embodiments, each of outer gate spacers 714 can have a pair of outer spacer portions 714S and an inner spacer portion 714N between the pair of outer spacer portions 714S. In some embodiments, each of inner spacer portions 714N can be disposed along sidewalls of top gate portion and on topmost nanostructured channel region (e.g., nanostructured layers 106).

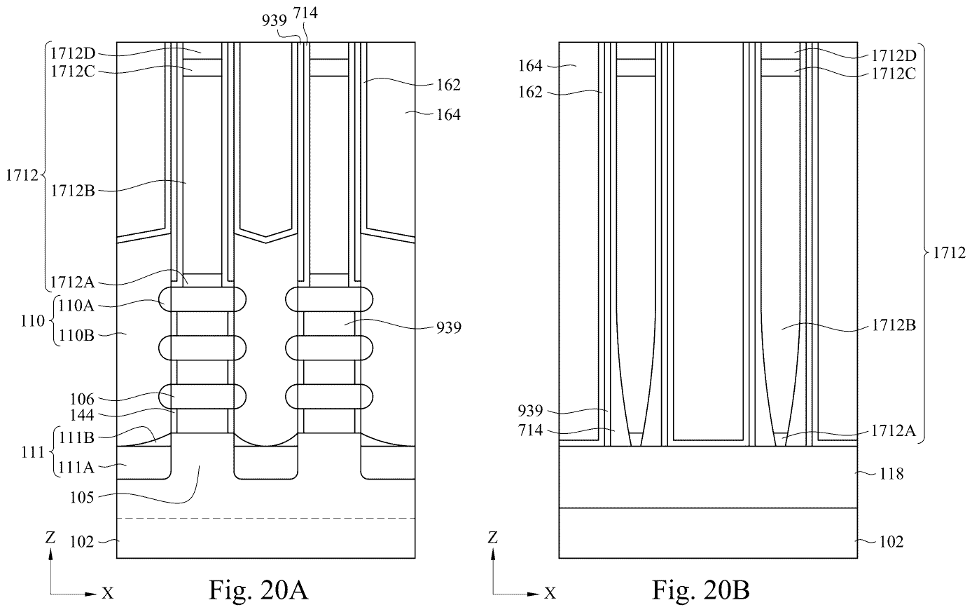

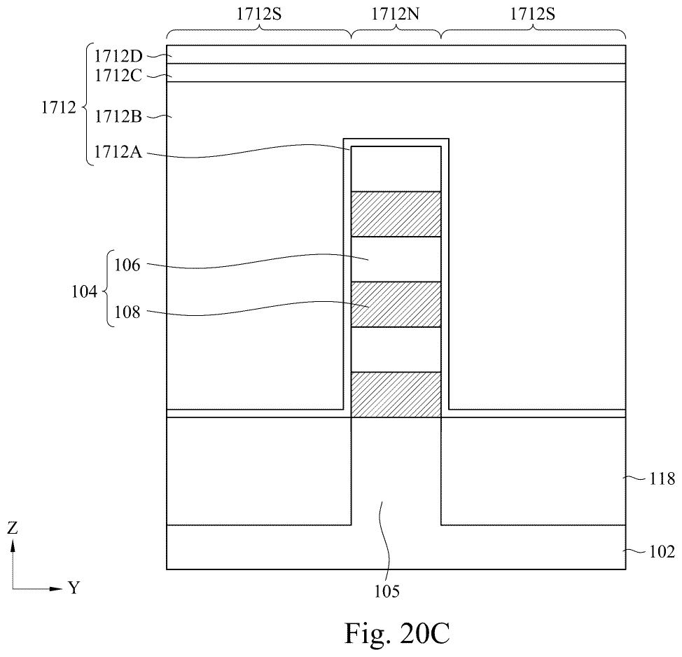

After the outer gate spacers 714 are formed, various processes described above with respect to FIGS. 7A-7C to 14A-14C are performed on the structures of FIGS. 19 and 19A-19C, resulting in the semiconductor device structure shown in FIGS. 20A, 20B, 20C.

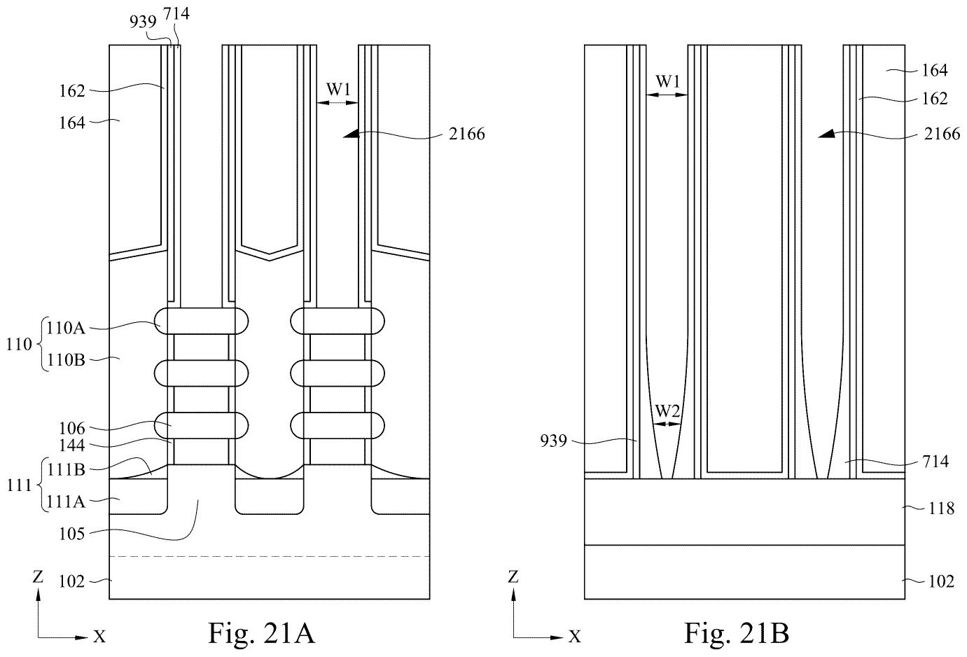

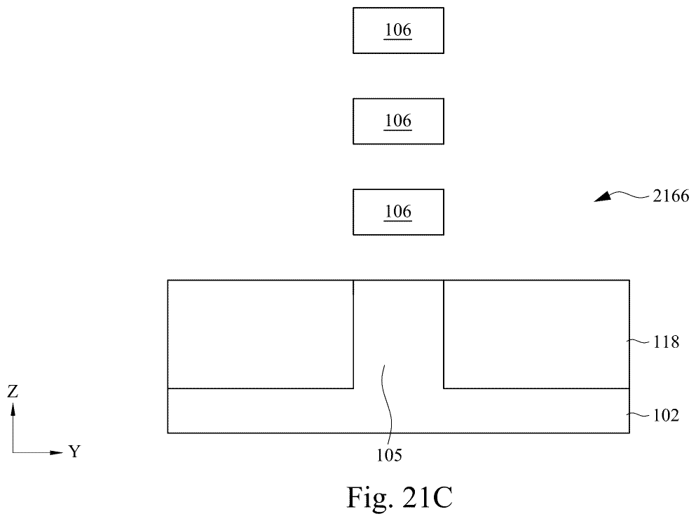

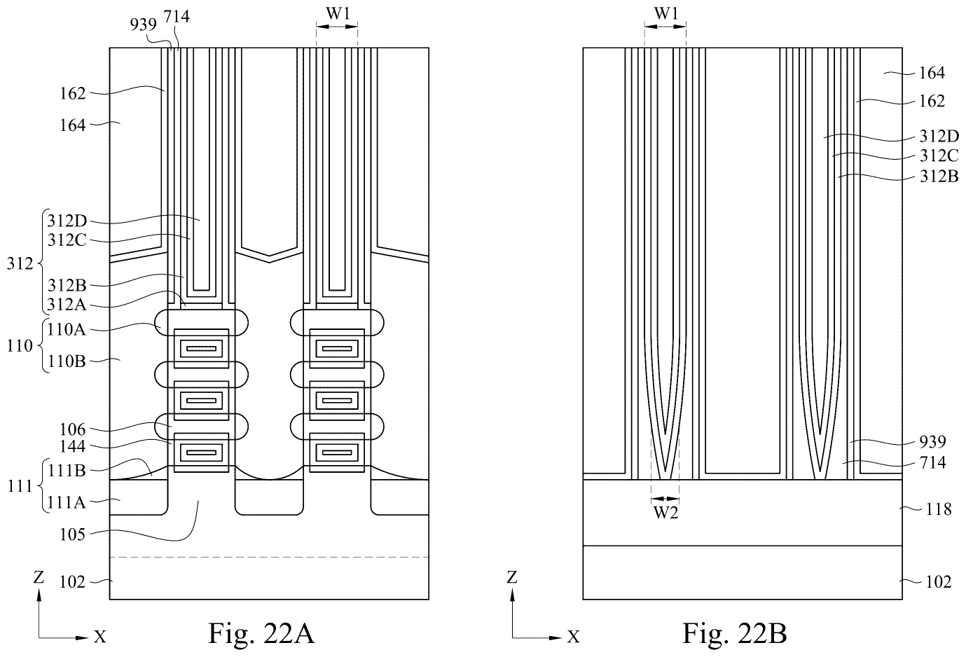

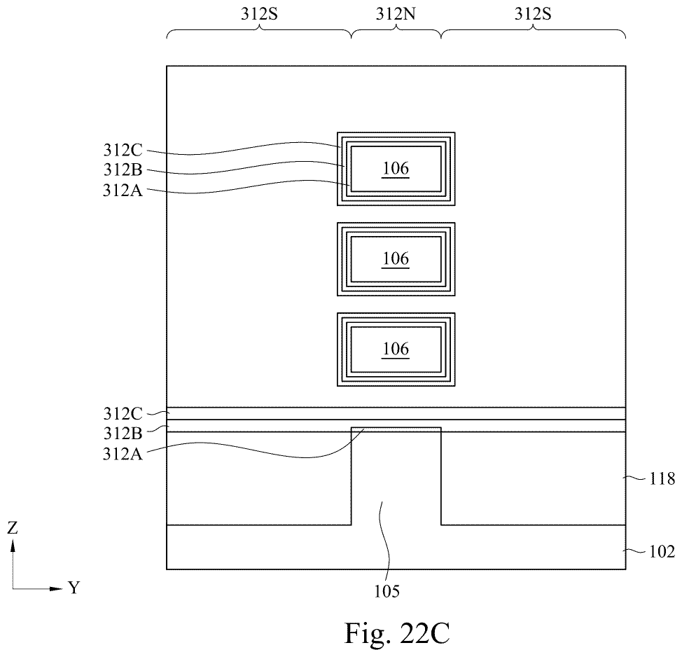

In FIGS. 21A, 21B, 21C, 22A, 22B, and 22C, the sacrificial gate structure 1712 and the sacrificial dielectric material 939 are removed and replaced with a GAA structure. For example, the sacrificial gate structures 1712 and sacrificial dielectric material 939 are replaced with GAA structures 312. The formation of GAA structures 312 can include sequential operations of: (i) etching sacrificial gate structures 1712 and sacrificial dielectric material 939 to form gate openings 2166, as shown in FIGS. 21A-21C, (ii) performing an oxidation process on the exposed regions of nanostructured layers 106 in gate openings 2166 to form IL layers 312A, as shown in FIGS. 22A and 22C (not visible in cross-sectional view of FIG. 22B), (iii) forming HK gate dielectric layers 312B on IL layers 312A, as shown in FIGS. 22A-22C, (iv) forming WFM layers 312C on HK gate dielectric layers 312B, as shown in FIGS. 23A-23C, and (v) forming conductive layers 312D on WFM layers 312C, as shown in FIGS. 22A-22C.

In some embodiments, the cross-sectional profiles of gate openings 2166 on STI region 118, as shown in FIG. 21B, can be similar to the cross-sectional profiles of polysilicon structures 1712B. Similar to polysilicon structures 212B (e.g., FIG. 13B), due to the tapered cross-sectional profiles of polysilicon structures 1712B, gate openings 2166 can be prevented from extending into STI regions 118 and base structure 105 during the etching of sacrificial gate structures 1712.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the S/D features is connected to a backside power rail (e.g., positive voltage VDD or negative voltage VSS) through the backside contacts.

The present disclosure provides example structures and methods for improving bottom surface profiles of bottom gate portion of a GAA structure, which increases the spacing between the bottom gate portion and the S/D regions. Increasing the spacing between the bottom gate portion and the S/D regions can reduce or minimize the parasitic capacitance in a GAA FET, which can improve the reliability and performance of the GAA FET. In some embodiments, the portion of the sacrificial gate structure on the STI region can be separated by a spacer to prevent the etching of the STI region during the removal of the sacrificial gate structure. In some embodiments, the portion of the sacrificial gate structure on the STI region can be formed with a tapered cross-sectional profile to prevent or minimize the etching of the STI region during the removal of the sacrificial gate structure. By modifying the sacrificial gate structure profiles, the bottom surface profiles of the bottom gate portion can be improved to reduce or minimize the parasitic capacitance in the GAA FET.

Various embodiments of the present disclosure also provide improved sheet formation process and etch profile control for forming source/drain trenches. The etch profile control is achieved by a cyclic process including an etch step, a passivation step, and a treatment step which allows the source/drain trenches to be formed with a straight vertical sidewall profile without a bowing profile. Prior to forming S/D features, sacrificial nanostructured layers between nanosheet channel layers are replaced with sacrificial dielectric layers. The sacrificial dielectric layers have minimum reaction with the nanosheet channel layers during subsequent high temperature process of S/D features and can be easily removed during sheet formation process. Since the integrity and surface profile of the nanosheet channel layers are preserved during the sheet formation process, a channel resistance between a source feature and a drain feature can be reduced. As a result, the device performance is improved.

An embodiment is a method for forming a semiconductor device structure. The method includes forming a fin structure from a substrate, the fin structure comprises a plurality of nanostructured layers and a plurality of sacrificial nanostructured layers alternatingly stacked, forming a shallow trench isolation (STI) region on the substrate, forming a sacrificial gate structure with a first gate portion suspended over the STI region and a second gate portion on the fin structure, removing the sacrificial nanostructured layers in the fin structure to form first cavities, filling the first cavities with a sacrificial dielectric layer, removing edge portions of each sacrificial dielectric layer to form second cavities, filling the second cavities with a dielectric spacer, forming a source/drain (S/D) feature, the S/D feature being in contact with the nanostructured layers and the dielectric spacers, and replacing the sacrificial gate structure and the sacrificial dielectric layer with a gate structure.

Another embodiment is a method for forming a semiconductor device structure. The method includes forming a fin structure from a substrate, wherein the fin structure comprises a plurality of nanostructured layers and a plurality of sacrificial nanostructured layers alternatingly stacked. The method also includes forming a shallow trench isolation (STI) region on the substrate, forming a sacrificial gate structure with a first gate portion in contact with the STI region and a second gate portion in contact with the fin structure. The method also includes removing, using a first etchant, a portion of the fin structure not covered by the sacrificial gate structure to form a trench with a first depth, modifying an etch selectivity of the exposed surfaces of the trench to a second etchant, subjecting the passivated surfaces to a treatment process, removing, using the second etchant, the passivated surface and a portion of the fin structure to form the trench with a second depth that is greater than the first depth, replacing the sacrificial nanostructured layers in the fin structure with a sacrificial dielectric layer, forming source/drain (S/D) features in the trench, removing the sacrificial dielectric layers, and surrounding a portion of each nanostructured layer with a gate electrode layer.

A further embodiment is a method for forming a semiconductor device structure. The method includes forming a fin structure from a substrate, wherein the fin structure comprises a plurality of nanostructured channel regions and a plurality of sacrificial nanostructured layers alternatingly stacked. The method also includes forming an isolation region on the substrate and adjacent to the fin structure, disposing a sacrificial gate structure over a portion of the fin structure. The sacrificial gate structure comprises an outer gate portion disposed on the isolation region, the outer gate portion is etched to have a first gate portion with a first profile and a second gate portion with a second profile that is different than the first profile. The sacrificial gate structure also includes an inner gate portion disposed on the fin structure. The method also includes removing a portion of the fin structure not covered by the sacrificial gate structure to form source/drain (S/D) openings, and forming a S/D feature in the S/D openings.

Yet another embodiment is a semiconductor device, comprising a substrate, a base structure with first and second base portions disposed on the substrate, an isolation region disposed on the substrate and adjacent to the base structure, a nanostructured channel region disposed on the first base portion, a source/drain region disposed on the second base portion, a gate structure, and a gate spacer disposed along sidewalls of the gate structure and between the gate structure and the isolation region. The gate structure includes an outer gate portion with a first structural profile and disposed over the isolation region and an inner gate portion with a second structural profile and disposed over the nanostructured channel region. The gate structure further includes a gate spacer disposed along sidewalls of the gate structure, wherein the gate spacer has an upper portion having a first thickness and a lower portion having a second thickness different than the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a fin structure from a substrate, the fin structure comprises a plurality of nanostructured layers and a plurality of sacrificial nanostructured layers alternatingly stacked;
forming a shallow trench isolation (STI) region on the substrate;
forming a sacrificial gate structure with a first gate portion suspended over the STI region and a second gate portion on the fin structure;
removing the sacrificial nanostructured layers in the fin structure to form first cavities;
filling the first cavities with a sacrificial dielectric layer;
removing edge portions of each sacrificial dielectric layer to form second cavities;
filling the second cavities with a dielectric spacer;
forming a source/drain (S/D) feature, the S/D feature being in contact with the nanostructured layers and the dielectric spacers; and
replacing the sacrificial gate structure and the sacrificial dielectric layer with a gate structure.

2. The method of claim 1, wherein forming the sacrificial gate structure comprises:
forming the first gate portion with a tapered cross-sectional profile; and
forming the second gate portion with a rectangular cross-sectional profile.

3. The method of claim 1, wherein forming the sacrificial gate structure comprises:
forming the first gate portion with a first width; and
forming the second gate portion with a second width smaller than the first width.

4. The method of claim 1, further comprising:
forming a gate spacer along sidewalls of the sacrificial gate structure and between the sacrificial gate structure and the STI region.

5. The method of claim 4, wherein forming the gate spacer comprises depositing a dielectric layer to cover a top surface and sidewalls of the sacrificial gate structure and to fill a gap between the sacrificial gate structure and the STI region.

6. The method of claim 1, wherein the sacrificial dielectric layer is made of an oxide.

7. The method of claim 1, wherein each of the sacrificial dielectric layer and the dielectric spacer includes a material chemically different from each other.

8. A method for forming a semiconductor device structure, comprising:
forming a fin structure from a substrate, the fin structure comprising a plurality of nanostructured layers and a plurality of sacrificial nanostructured layers alternatingly stacked;
forming a shallow trench isolation (STI) region on the substrate;
forming a sacrificial gate structure with a first gate portion in contact with the STI region and a second gate portion in contact with the fin structure;
removing, using a first etchant, a portion of the fin structure not covered by the sacrificial gate structure to form a trench with a first depth;
modifying an etch selectivity of the exposed surfaces of the trench to a second etchant;
subjecting the passivated surfaces to a treatment process;
removing, using the second etchant, the passivated surface and a portion of the fin structure to form the trench with a second depth that is greater than the first depth;
replacing the sacrificial nanostructured layers in the fin structure with a sacrificial dielectric layer;
forming source/drain (S/D) features in the trench;
removing the sacrificial dielectric layers; and
surrounding a portion of each nanostructured layer with a gate electrode layer.

9. The method of claim 8, wherein the sacrificial dielectric layer is made of an oxide.

10. The method of claim 8, wherein the etch selectivity of the exposed surfaces of the trench is modified by forming a passivation layer on the exposed surfaces of a first section of the trench.

11. The method of claim 10, wherein the passivation layer is formed by exposing the exposed surfaces of the first section of the trench to a gas mixture comprising an oxygen-containing precursor or a nitrogen-containing precursor.

12. The method of claim 10, wherein the treatment process is performed by bombarding the passivation layer with neutral radical of species formed from a nitrogen-containing gas and/or a hydrogen-containing gas.

13. The method of claim 8, wherein the first and second etchants comprise a hydrocarbon-based etch chemistry, a bromine-based etch chemistry, a chlorine-based etch chemistry, and/or a fluorine-based etch chemistry.

14. The method of claim 8, wherein forming the sacrificial gate structure comprises:
forming the first gate portion with a tapered cross-sectional profile; and
forming the second gate portion with a rectangular cross-sectional profile.

15. A semiconductor device, comprising:
a substrate;
a base structure with first and second base portions disposed on the substrate;
an isolation region disposed on the substrate and adjacent to the base structure;
a nanostructured channel region disposed on the first base portion;
a source/drain region disposed on the second base portion;
a gate structure, comprising:
an outer gate portion comprising a first structural profile and disposed over the isolation region, and
an inner gate portion comprising a second structural profile and disposed over the nanostructured channel region, wherein the second structural profile is different than the first structural profile;
a gate spacer disposed along sidewalls of the gate structure, wherein the gate spacer has an upper portion having a first thickness and a lower portion having a second thickness different than the first thickness.

16. The semiconductor device of claim 15, wherein the first structural profile is a tapered cross-sectional profile and the second structural profile is a non-tapered cross-sectional.

17. The semiconductor device of claim 15, wherein the second thickness is greater than the first thickness.

18. The semiconductor device of claim 17, wherein the outer gate portion is separated from the isolation region by the gate spacer.

19. The semiconductor device of claim 17, wherein the outer gate portion is separated from the isolation region by an oxide layer.

20. The semiconductor device of claim 19, wherein the lower portion of the gate spacer is in contact with sidewalls of the oxide layer.
